(19) United States
(12) Patent Application Publication
(10) Pub. No.: US 2025/0248270 A1
(43) Pub. Date: Jul. 31, 2025

(54) DISPLAY DEVICE AND METHOD OF MANUFACTURING THE SAME

(71) Applicant: LG Display Co., Ltd., Seoul (KR)

(72) Inventors: Huiseong YU, Paju-si (KR); Joohwan HWANG, Paju-si (KR); Hyejin KIM, Paju-si (KR); Wooseok NOH, Paju-si (KR); Youngjune GO, Paju-si (KR)

(21) Appl. No.: 18/972,475

(22) Filed: Dec. 6, 2024

(30) Foreign Application Priority Data
Jan. 30, 2024 (KR) 10-2024-0013759

(51) Int. Cl. H10K 59/80; H10K 59/12; H10K 59/122

(52) U.S. Cl. CPC H10K 59/8722; H10K 59/1201; H10K 59/122

(57) ABSTRACT

A display device according to embodiments of the present disclosure may include a substrate including a display area and a non-display area adjacent to the display area. The display device includes an insulating layer located on the substrate. The display device includes a bank located on the insulating layer and having a bank hole. The display device includes a first inorganic layer located on the bank. The display device includes an organic layer located on the first inorganic layer. The display device includes a blocking pattern layer located on the first inorganic layer, disposed on a side of the organic layer, and overlapping with at least a portion of an edge portion of the bank. The display device includes a second inorganic layer located on the organic layer and extending above the blocking pattern layer.

### CROSS-REFERENCE TO RELATED APPLICATION

This application claims priority from Korean Patent Application No. 10-2024-0013759, filed on Jan. 30, 2024, which is hereby incorporated by reference for all purposes as if fully set forth herein.

### BACKGROUND

### Technical Field

Embodiments of the present disclosure relate to a display device and a method of manufacturing the same.

### Description of the Related Art

A display panel of a display device may include an organic layer, and the organic layer may spread during the process. Therefore, the display panel requires a structure to prevent the organic layer from spreading.

In addition, the display panel of a display device may include a display area where images are displayed and a non-display area where images are not displayed, and various structures, various circuits, and lines are required to be disposed in the non-display area (also called “bezel”), so that it is not easy to reduce the bezel of the display panel. In particular, in the case that a structure to prevent the organic layer from spreading is formed on the bezel of the display panel, it is more difficult to reduce the bezel size.

### BRIEF SUMMARY

Embodiments of the present disclosure may provide a display device capable of effectively preventing the spread and overflow of an organic layer.

Embodiments of the present disclosure may provide a display device having a structure capable of effectively preventing the spread and overflow of an organic layer while implementing an extremely narrow bezel.

Embodiments of the present disclosure may provide a display device having a structure capable of effectively preventing the spread and overflow of an organic layer, implementing an extremely narrow bezel, and also performing a moisture absorption function.

A display device according to embodiments of the present disclosure may include a substrate including a display area and a non-display area, an insulating layer located on the substrate, a bank located on the insulating layer and having a bank hole, a first inorganic layer located on the bank, an organic layer located on the first inorganic layer, a blocking pattern layer located on the first inorganic layer, disposed on a side of the organic layer, and overlapping with at least a portion of an edge portion of the bank, and a second inorganic layer located on the organic layer and extending above the blocking pattern layer.

In a display device according to embodiments of the present disclosure, the blocking pattern layer may include an inorganic pattern layer on the first inorganic layer, and an organic pattern layer disposed on an outer side of the inorganic pattern layer.

In a display device according to embodiments of the present disclosure, the inorganic pattern layer may be formed by connecting patterns having a circular or oval shape.

In a display device according to embodiments of the present disclosure, the organic pattern layer may include a getter.

In a display device according to embodiments of the present disclosure, the inorganic pattern layer may include a first inorganic pattern layer on the first inorganic layer, and a second inorganic pattern layer on the first inorganic pattern layer.

In a display device according to embodiments of the present disclosure, the inorganic pattern layer may be disposed surrounding the display area, and the organic pattern layer may be disposed surrounding the inorganic pattern layer.

A method of manufacturing a display device according to embodiments of the present disclosure may including disposing an insulating layer on a substrate including a display area and a non-display area, disposing a bank having a bank hole for defining an emission area on the insulating layer, and disposing a first inorganic layer on the bank; disposing a blocking pattern layer on the first inorganic layer, and disposing the blocking pattern layer to overlap with at least a portion of an edge portion of the bank; disposing an organic layer on the first inorganic layer, and disposing the organic layer on an inner surface of the blocking pattern layer; and disposing a second inorganic layer on the organic layer and the blocking pattern layer, and disposing the second inorganic layer so that the second inorganic layer extends to an outer side of the blocking pattern layer.

In the method of manufacturing a display device according to embodiments of the present disclosure, in disposing the blocking pattern layer, the blocking pattern layer may include an inorganic pattern layer on the first inorganic layer, an organic sacrificial layer on the inorganic pattern layer, and an organic pattern layer disposed on an outer side of the inorganic pattern layer.

In the method of manufacturing a display device according to embodiments of the present disclosure, the organic pattern layer may include a getter.

In the method of manufacturing a display device according to embodiments of the present disclosure, in disposing the blocking pattern layer, the inorganic pattern layer may include a first inorganic pattern layer on the first inorganic layer, and a second inorganic pattern layer on the first inorganic pattern layer.

The method of manufacturing a display device according to embodiments of the present disclosure may further include removing the organic sacrificial layer before disposing the second inorganic layer.

In the method of manufacturing a display device according to embodiments of the present disclosure, in disposing the second inorganic layer, the blocking pattern layer may include the first inorganic pattern layer, the second inorganic pattern layer, and the organic pattern layer.

According to embodiments of the present disclosure, there may provide a display device capable of effectively preventing the spread and overflow of an organic layer.

According to embodiments of the present disclosure, there may provide a display device having a structure capable of effectively preventing the spread and overflow of an organic layer while implementing an extremely narrow bezel.

According to embodiments of the present disclosure, there may provide a display device having a structure capable of effectively preventing the spread and overflow of an organic layer, implementing an extremely narrow bezel, and also performing a moisture absorption function.

According to embodiments of the present disclosure, it is possible to reduce the weight of a display device by having an extremely narrow bezel structure.

### BRIEF DESCRIPTION OF THE SEVERAL VIEWS OF THE DRAWINGS

FIG. 1 is a system configuration diagram of a display device according to embodiments of the present disclosure.

FIG. 2 illustrates a display panel according to embodiments of the present disclosure.

FIG. 3 is a cross-sectional view of a display panel according to embodiments of the present disclosure.

FIG. 4 is a plan view of a display panel according to embodiments of the present disclosure.

FIG. 5 is a cross-sectional view of an outer area of a display panel according to embodiments of the present disclosure.

FIG. 6 is a plan view of a display panel according to embodiments of the present disclosure, including a blocking pattern area and a blocking pattern layer disposed thereon.

FIGS. 7A and 7B are plan views of a display panel according to embodiments of the present disclosure, and illustrate a display panel including a vertically stacked blocking pattern layer.

FIGS. 8 and 9 are cross-sectional views of a display panel according to embodiments of the present disclosure, and illustrate cross-sectional views of a display panel including a vertically stacked blocking pattern layer.

FIGS. 10A and 10B illustrate end positions of main layers of a display panel according to embodiments of the present disclosure.

FIGS. 11 to 15 illustrate a method of manufacturing a display device according to embodiments of the present disclosure.

FIGS. 16A and 16B are diagrams for explaining a structure of a vertically stacked blocking pattern layer in a display panel according to embodiments of the present disclosure.

FIG. 17 is a plan view of a display panel according to embodiments of the present disclosure, and illustrates a plan view of the display panel including a horizontally stacked blocking pattern layer.

FIGS. 18 and 19 are cross-sectional views of a display panel according to embodiments of the present disclosure, and illustrate the cross-sectional views of a display panel including a horizontally stacked blocking pattern layer.

FIGS. 20A and 20B illustrate end positions of main layers of a display panel according to embodiments of the present disclosure.

FIG. 21 is a diagram for explaining a structure of a blocking pattern layer in a display panel according to embodiments of the present disclosure.

### DETAILED DESCRIPTION

Hereinafter, embodiments of the disclosure are described in detail with reference to the accompanying drawings. In assigning reference numerals to components of each drawing, the same components may be assigned the same numerals even when they are shown on different drawings. When determined to make the subject matter of the disclosure unclear, the detailed of the known art or functions may be skipped. As used herein, when a component “includes,” “has,” or “is composed of” another component, the component may add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” may be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components may be directly “connected”, “coupled” or “linked” “, or another component may intervene. Here, the other component may be included in one or more of the two or more components that are “connected”, “coupled” or “linked” to each other.

The text “A and/or B” as used herein should be understood to include “only A, only B, or both A and B.”

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Hereinafter, various embodiments of the disclosure are described in detail with reference to the accompanying drawings.

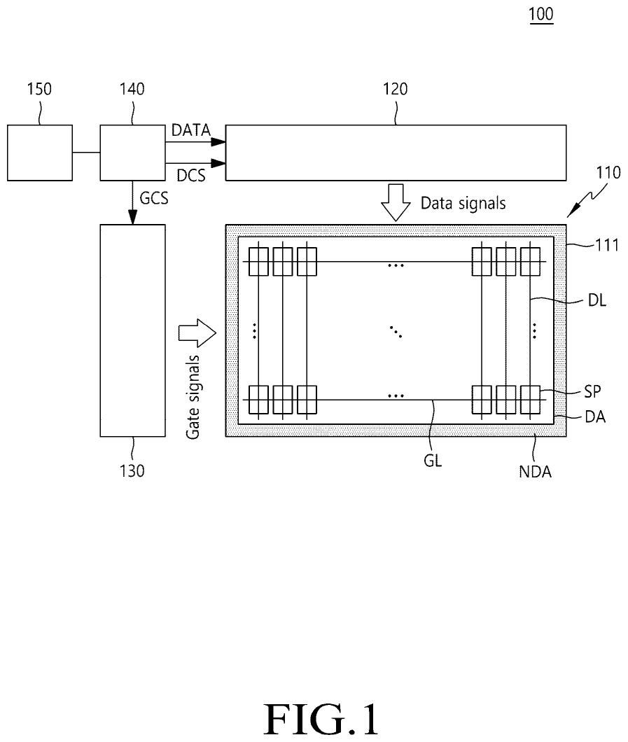

FIG. 1 is a system configuration diagram of a display device 100 according to embodiments of the present disclosure.

Referring to FIG. 1, a display device 100 according to embodiments of the present disclosure may include a display panel 110 and a display driving circuit as components for displaying an image. The display driving circuit is a circuit for driving the display panel 110, and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA located outside the display area DA.

A plurality of subpixels SP for image display may be disposed in the display area DA, and the non-display area NDA may include a pad area PA located in a first direction from the display area DA.

In a display panel 110 according to embodiments of the present disclosure, the non-display area NDA may be very small. In this specification, the non-display area NDA may be also referred to as a “bezel.”

For example, the non-display area NDA may include a first non-display area located outside the display area DA in a first direction, a second non-display area located outside the display area DA in a second direction different from the first direction, a third non-display area located outside the display area DA in the opposite direction to the first direction, and a fourth non-display area located outside the display area DA in the direction opposite to the second direction. One or both of the first to fourth non-display areas may include a pad area to which the data driving circuit 120 is connected or bonded. Among the first to fourth non-display areas, two or three without the pad area may be very small in size. For example, the first non-display area may include a pad area, and the sizes of the second non-display area, third non-display area, and fourth non-display area may be very small.

For another example, a boundary area between the display area DA and the non-display area NDA may be bent so that the non-display area NDA may be located below the display area. In this case, when the user looks at the display device 100 from the front, there may be little or no non-display area NDA visible to the user.

Various types of signal lines for driving a plurality of subpixels SP may be disposed on the substrate 111 of the display panel 110.

The display device 100 according to embodiments of the present disclosure may be a liquid crystal display device or the like, or may be a self-luminous display device in which the display panel 110 emits light by itself. When the display device 100 according to embodiments of the present disclosure is a self-luminous display device, each of the plurality of subpixels SP may include a light emitting device.

For example, the display device 100 according to embodiments of the present disclosure may be an organic light emitting display device in which a light emitting device is implemented as an organic light emitting diode (OLED). For another example, the display device 100 according to embodiments of the present disclosure may be an inorganic light emitting display device in which the light emitting device is implemented as an inorganic-based light emitting diode. For another example, the display device 100 according to embodiments of the present disclosure may be a quantum dot display device in which a light emitting device is implemented with quantum dots, which are semiconductor crystals emitting light by itself.

The structure of each of the plurality of subpixels SP may vary depending on the type of the display device 100. For example, if the display device 100 is a self-luminous display device with the subpixel SP emitting light by itself, each subpixel SP may include a self-luminous light emitting device, one or more transistors, and one or more capacitors.

For example, various types of signal lines may include a plurality of data lines DL supplying data signals (also called data voltages or image signals) and a plurality of gate lines GL for transmitting gate signals (also called scan signals).

For example, the plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction. Hereinafter, for convenience of explanation, it will exemplified a case in which each of the plurality of data lines DL is arranged in a column direction, and each of the plurality of gate lines GL is arranged in a row direction.

The data driving circuit 120 is a circuit for driving a plurality of data lines DL, and may output data signals to the plurality of data lines DL.

The data driving circuit 120 may receive image data in digital form from the display controller 140 and convert the received image data into analog data signals to output to a plurality of data lines DL.

For example, the data driving circuit 120 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The data driving circuit 120 may be connected to one side (e.g., the upper or lower side) of the display panel 110. Depending on the driving method, panel design method, etc., the data driving circuit 120 may be connected to both sides (e.g., upper and lower sides) of the display panel 110, or may be connected to two or more of the four sides of the display panel 110.

The data driving circuit 120 may be connected to the outside of the display area DA of the display panel 110, but alternatively, it may be disposed in the display area DA of the display panel 110.

The gate driving circuit 130 is a circuit for driving a plurality of gate lines GL, and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

In the display device 100 according to embodiments of the present disclosure, the gate driving circuit 130 may be built into the display panel 110 as a gate-in-panel (GIP) type. If the gate driving circuit 130 is a gate-in-panel type, the gate driving circuit 130 may be formed on a substrate of the display panel 110 during the manufacturing process of the display panel 110.

In the display device 100 according to embodiments of the present disclosure, the gate driving circuit 130 may be disposed in the display area DA of the display panel 110. For example, the gate driving circuit 130 may be disposed in a first partial area within the display area DA (e.g., a left area or a right area within the display area DA). For another example, the gate driving circuit 130 may be disposed in a first partial area within the display area DA (e.g., a left area or a right area within the display area DA) and a second partial area (e.g., a right area or a left area within the display area DA). As another example, the gate driving circuit 130 may be distributed and disposed throughout the display area DA.

In the present disclosure, a gate driving circuit 130 built into the display panel 110 as a gate-in-panel type may be referred to as a “gate-in-panel circuit.”

As described above, the gate driving circuit 130 of the gate-in-panel type is not connected to or disposed in the non-display area NDA of the display panel 110, but is disposed in the display area DA, so that the bezel of the display panel 110 may be significantly reduced.

The display controller 140 may be a device for controlling the data driving circuit 120 and the gate driving circuit 130, and may control the driving timing for the plurality of data lines DL and the driving timing of the plurality of gate lines GL.

The display controller 140 may supply a data driving control signal DCS to the data driving circuit 120 to control the data driving circuit 120, and may supply a gate driving control signal GCS to the gate driving circuit 130 to control the gate driving circuit 130.

The display controller 140 may receive input image data from a host system 150 and supply image data DATA to the data driving circuit 120 based on the input image data.

The display controller 140 may be implemented as a separate component from the data driving circuit 120, or may be integrated with the data driving circuit 120 and implemented as an integrated circuit.

The display controller 140 may be a timing controller used in typical display technology, or may be a control device capable of further performing other control functions including a timing controller, or may be a control device different from the timing controller, or may be a control device other than a timing controller, or may be a circuit within the control device. The display controller 140 may be implemented with various circuits or electronic components, such as an integrated circuit (IC), a field programmable gate array (FPGA), an application specific integrated circuit (ASIC), or Processor.

The display controller 140 may be mounted on a printed circuit board, a flexible printed circuit, etc., and may be electrically connected to the data driving circuit 120 and the gate driving circuit 130 through a printed circuit board, a flexible printed circuit.

The display controller 140 may transmit and receive signals with the data driving circuit 120 according to one or more predetermined interfaces. For example, the interface may include a low voltage differential signaling (LVDS) interface, an embedded clock point-point interface (EPI) interface, or a serial peripheral interface (SPI).

In order to provide not only an image display function but also a touch sensing function, the display device 100 according to embodiments of the present disclosure may include a touch sensor and a touch sensing circuit for detecting an occurrence of a touch by a touch object such as a finger or pen or detection a touch position by sensing the touch sensor.

The touch sensing circuit may include a touch driving circuit for driving and sensing a touch sensor to generate and output touch sensing data, and a touch controller for detecting the occurrence of a touch or detecting the touch position using touch sensing data.

A touch sensor may include a plurality of touch electrodes. The touch sensor may further include a plurality of touch lines to electrically connect a plurality of touch electrodes and the touch driving circuit.

The touch sensor may exist outside the display panel 110 in the form of a touch panel or may exist inside the display panel 110. If the touch sensor exists outside the display panel 110 in the form of a touch panel, the touch sensor may be referred to as an external type. If the touch sensor is an external type, the touch panel and the display panel 110 may be manufactured separately and combined during the assembly process. The external touch panel may include a touch panel substrate and a plurality of touch electrodes on the touch panel substrate.

If the touch sensor exists inside the display panel 110, the touch sensor may be formed on the substrate along with signal lines and electrodes related to display driving during the manufacturing process of the display panel 110.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

If the touch sensing circuit performs touch sensing using a self-capacitance sensing method, the touch sensing circuit may perform touch sensing based on the capacitance between each touch electrode and a touch object (e.g., finger, pen, etc.). According to the self-capacitance sensing method, each of the plurality of touch electrodes may serve as a driving touch electrode and a sensing touch electrode. The touch driving circuit may drive all or part of the plurality of touch electrodes and sense all or part of the plurality of touch electrodes.

If the touch sensing circuit performs touch sensing using the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit and the touch controller included in the touch sensing circuit may be implemented as separate devices or as one device. Additionally, the touch driving circuit and the data driving circuit may be implemented as separate devices or as one device.

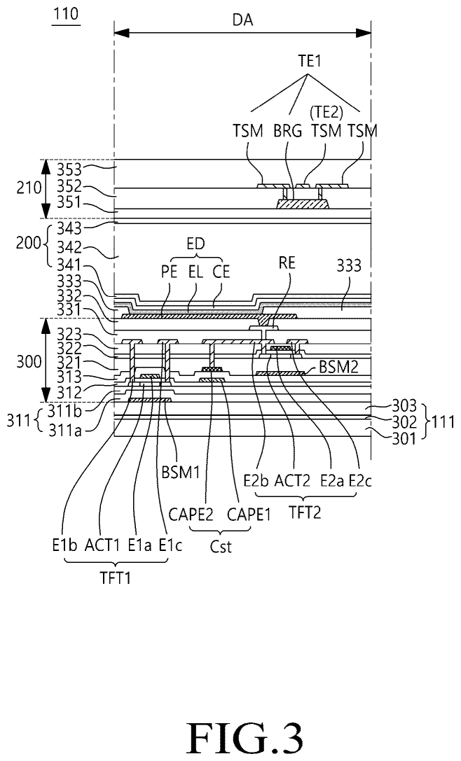

Meanwhile, a plurality of touch lines (e.g., a plurality of touch routing lines) for electrically connecting a plurality of touch electrodes constituting the touch sensor and the touch driving circuit may be disposed across the display area DA and extend into the pad area (e.g., pad area PA in FIG. 3) without bypassing the non-display area (e.g., a second and third non-display areas NDA2, NDA3 and NDA4 of FIG. 3) in which there is no pad area (e.g., pad area PA of FIG. 3) among the non-display areas NDA.

Accordingly, there may significantly reduce the size of the non-display area (e.g., a second and third non-display areas NDA2, NDA3 and NDA4 of FIG. 3) in which there is no pad area (e.g., pad area PA of FIG. 3) among the non-display areas NDA, thereby significantly reducing the bezel size.

The display device 100 may further include a power supply circuit which supplies various types of power to the display driving circuit and/or the touch sensing circuit.

The display device 100 according to embodiments of the present disclosure may be a mobile terminal such as a smart phone or tablet, or a monitor or television of various sizes, but is not limited thereto, and may be a display of various types and sizes capable of displaying information or images.

The display device 100 according to embodiments of the present disclosure may further include an electronic device such as a camera (e.g., image sensor) and a detection sensor. For example, the detection sensor may be a sensor for detecting an object or a human body by receiving light such as infrared, ultrasonic, or ultraviolet rays.

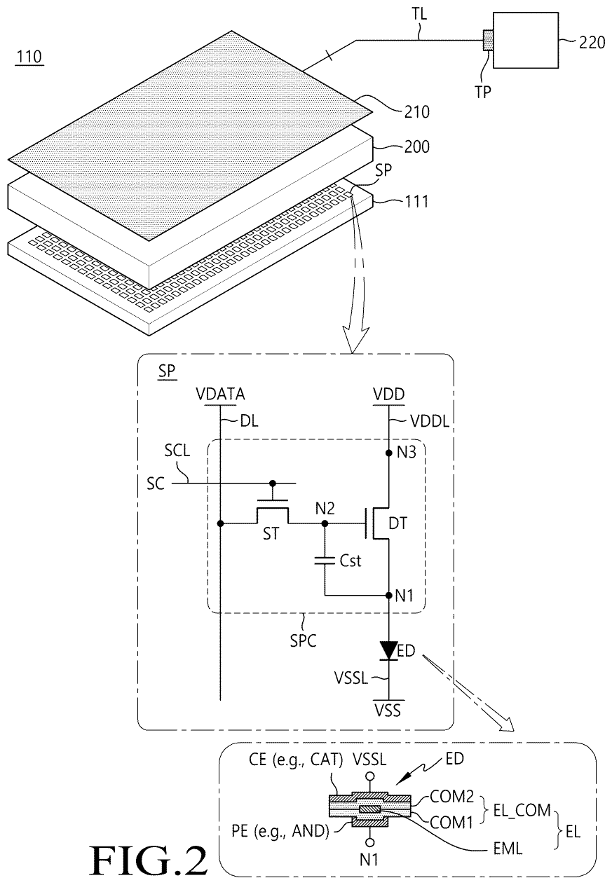

FIG. 2 illustrates a display panel 110 according to embodiments of the present disclosure.

Referring to FIG. 2, the display panel 110 may include a substrate 111 disposed in a plurality of subpixels SP and an encapsulation layer 200 on the substrate 111. Here, the encapsulation layer 200 may also be referred to as an encapsulation substrate or an encapsulation portion.

Referring to FIG. 2, when the display device 100 according to embodiments of the present disclosure is a self-luminous display device, each of the plurality of subpixels SP may include a light emitting device ED and a subpixel circuit SPC for driving the light emitting device ED.

Referring to FIG. 2, the subpixel circuit SPC may include a plurality of pixel driving transistors and at least one capacitor for driving the light emitting device ED. In the present disclosure, the subpixel circuit SPC may drive the light emitting device ED by supplying a driving current to the light emitting device ED at a predetermined timing. The light emitting device ED may be driven by a driving current and emit light.

The plurality of pixel driving transistors may include a driving transistor DT for driving the light emitting device ED, and a scan transistor ST which is turned on or off depending on the scan signal SC.

The driving transistor DT may supply driving current to the light emitting device ED.

The scan transistor ST may be configured to control the electrical state of a corresponding node in the subpixel circuit SPC or to control the state or operation of the driving transistor DT.

At least one capacitor may include a storage capacitor Cst to maintain a constant voltage during the frame.

In order to drive the subpixel SP, a data signal VDATA which is an image signal, and a scan signal SC which is a gate signal may be applied to the subpixel SP. In addition, a common pixel driving voltage including a first common driving voltage VDD and a second common driving voltage VSS may be applied to the subpixel SP in order to drive the subpixel SP.

The light emitting device ED may include a pixel electrode PE, an intermediate layer EL, and a common electrode CE. The intermediate layer EL may be located between the pixel electrode PE and the common electrode CE.

For example, the pixel electrode PE may be an anode AND, and the common electrode CE may be a cathode CAT. Alternatively, the pixel electrode PE may be a cathode CAT and the common electrode CE may be an anode AND. Hereinafter, for convenience of explanation, it is exemplified a case where the pixel electrode PE is an anode AND and the common electrode CE is a cathode CAT.

In the case that the light emitting device ED is an organic light emitting device, the intermediate layer EL may include an emission layer EML, a first common intermediate layer COM1 between the anode AND and the emission layer EML, and a second common intermediate layer COM2 between the emission layer EML and the cathode CAT.

The emission layer EML may be disposed in each subpixel SP. In comparison, the first common intermediate layer COM1 and the second common intermediate layer COM2 may be commonly disposed across a plurality of subpixels SP. The emission layer EML may be disposed in each emission area, and the first common intermediate layer COM1 and the second common intermediate layer COM2 may be commonly disposed across a plurality of emission areas and non-emission areas. The first common intermediate layer COM1 and the second common intermediate layer COM2 may be collectively referred to as the common intermediate layer EL_COM.

For example, the first common intermediate layer COM1 may include a hole injection layer HIL and a hole transport layer HTL. The second common intermediate layer COM2 may include an electron transport layer ETL and an electron injection layer EIL. The hole injection layer may inject holes from the anode AND to the hole transport layer, the hole transport layer may transport holes to the emission EML, the electron injection layer may inject electrons from the cathode CAT to the electron transport layer, and the electron transport layer may transport electrons to the emission layer EML.

For example, the cathode CAT may be electrically connected to a second common driving voltage line VSSL. A second common driving voltage VSS, which is a type of common pixel driving voltage, may be applied to the cathode CAT through the second common driving voltage line VSSL. The anode AND may be electrically connected to a first node N1 of the driving transistor DT of each subpixel SP. In the present disclosure, the second common driving voltage VSS may also be referred to as a base voltage VSS, and the second common driving voltage line VSSL may also be referred to as a base voltage line VSSL.

For example, the pixel electrode PE may be an electrode disposed in each subpixel SP, and the common electrode CE may be an electrode commonly disposed in a plurality of subpixels SP.

Each light emitting device ED may be composed of overlapping parts of the pixel electrode PE, the intermediate layer EL and the common electrode CE. A predetermined emission area may be formed by each light emitting device ED. For example, the emission area of each light emitting device ED may include an area where the pixel electrode PE, the intermediate layer EL and the common electrode CE overlap.

For example, the light emitting device ED may be an organic light emitting diode (OLED), an inorganic light emitting diode, or a quantum dot light emitting device. For example, in the case that the light emitting device ED is an organic light emitting diode OLED, the intermediate layer EL in the light emitting device ED may include an organic intermediate layer EL containing an organic material.

The driving transistor DT may be a driving transistor for supplying driving current to the light emitting device ED. The driving transistor DT may be connected between a first common driving voltage line VDDL and the light emitting device ED.

The driving transistor DT may include a first node N1 electrically connected to the light emitting device ED, a second node N2 to which the data signal VDATA is applied, and a third node N3 to which the driving voltage VDD is applied from the driving voltage line DVL.

In the driving transistor DT, the second node N2 may be a gate node, the first node N1 may be a source node or a drain node, and the third node N3 may be a drain node or a source node. Hereinafter, for convenience of explanation, it will be described a case in which the second node N2 is a gate node, the first node N1 is a source node, and the third node N3 is a drain node in the driving transistor DT.

The scan transistor ST included in the subpixel circuit SPC illustrated in FIG. 2 may be a switching transistor for transmitting a data signal VDATA, which is an image signal, to the second node N2 which is the gate node of the driving transistor DT.

The scan transistor ST may be controlled on-off by the scan signal SC which is a gate signal applied through the scan line SCL as a type of gate line GL, and may control the electrical connection between the second node N2 of the driving transistor DT and the data line DL. The drain electrode or source electrode of the scan transistor ST may be electrically connected to the data line DL, and the source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed outside the driving transistor DT rather than a parasitic capacitor (e.g., Cgs, Cgd) as an internal capacitor which may exist between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

If the display panel 110 has a top emission structure, at least a portion of the subpixel circuit SPC may overlap with at least a portion of the light emitting device ED in the vertical direction. Alternatively, if the display panel 110 has a bottom emission structure, the subpixel circuit SPC may not overlap with the light emitting device ED in the vertical direction.

As shown in FIG. 2, the subpixel circuit SPC may have 2T-1C structure including two transistors T1 and T2 and one capacitor Cst. In some case, the subpixel circuit SPC may further include one or more transistors or one or more capacitors.

For example, the subpixel circuit SPC may have a 8T-1C structure including eight transistors and a single capacitor. For another example, the subpixel circuit SPC may have a 6T-2C structure including six transistors and two capacitors. For another example, the subpixel circuit SPC may have a 7T-1C structure including seven transistors and one capacitor.

Depending on the structure of the subpixel circuit SPC, there may vary the type and number of gate signal and/or gate lines supplied to the subpixel SP.

In addition, depending on the structure of the subpixel circuit SPC, there may vary the type and number of common pixel driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 may be disposed on the display panel 110 to prevent oxygen from penetrating into the circuit elements (particularly, the light emitting device ED). The encapsulation layer 200 may be configured in various shapes to prevent the light emitting device ED from coming into contact with moisture or oxygen.

Referring to FIG. 2, in order to sense a touch of an user, the display device 100 according to embodiments of the present disclosure may include a touch sensor layer 210 including a plurality of sensor electrodes, and touch sensing circuit 220 configured to determine the presence or absence of a touch or touch coordinates by sensing a plurality of sensor electrodes.

The touch sensor layer 210 may be built or embedded into the display panel 110. For example, the touch sensor layer 210 may be disposed on the encapsulation layer 200 within the display panel 110.

The display panel 110 may include a touch sensor layer 210, and may further include a plurality of touch pads to which the touch sensing circuit 210 is electrically connected, and a plurality of touch routing lines TL for electrically connecting a plurality of sensor electrodes included in the touch sensor layer 210 and a plurality of touch pads to which the touch sensing circuit 220 is connected.

Meanwhile, the display device 100 according to an embodiment of the present disclosure may have an extremely narrow bezel structure in which the non-display area NDA of the display panel 110 is very small or almost absent. Hereinafter, it will be described the extremely narrow bezel structure of the display panel 110 of the display device 100 according to an embodiment of the present disclosure.

FIG. 3 is a cross-sectional view of a display panel 110 according to embodiments of the present disclosure.

Referring to FIG. 3, the display panel 110 according to embodiments of the present disclosure may include a transistor forming part 300, a light emitting device forming part, and an encapsulation part based on a vertical structure.

The substrate 111 may be a single layer or a multi-layer. When the substrate 111 is a multi-layer, the substrate 111 may include a first substrate 301, an intermediate substrate layer 302, and a second substrate 303. The substrate intermediate layer 302 may be located between the first substrate 301 and the second substrate 303. For example, each of the first substrate 301 and the second substrate 303 may be a polyimide (PI) layer. The substrate intermediate layer 302 may be an inorganic insulating layer. When a charge is charged to the first substrate 301 which is a polyimide layer, the substrate intermediate layer 302 may prevent charges from affecting transistors disposed on the second substrate 303 through the second substrate 303 which is a polyimide layer.

In addition, the substrate intermediate layer 302 may block moisture components from penetrating upward through the first substrate 301. For example, the substrate intermediate layer 302 may be formed of a single layer of silicon nitride (SiNx) or silicon oxide (SiOx) or a multilayer thereof, or may be formed of a double layer of silicon dioxide (SiO₂) and silicon nitride (SiNx), but is not limited thereto.

The transistor forming part 300 may include a substrate 111, various insulating layers 311, 312, 313, 321, 322 and 323 on the substrate 111, various transistors TFT1 and TFT2, a storage capacitor Cst, and various electrodes or signal lines.

The transistors TFT1 and TFT2 included in the transistor forming part 300 may include a first transistor TFT1 and a second transistor TFT2.

The first transistor TFT1 may include a first active layer ACT1, a first electrode Ela, a second electrode Elb, and a third electrode Elc. The first active layer ACT1 may be a first semiconductor layer, but embodiments of the present disclosure are not limited thereto. For example, the first active layer ACT1 may be made of an oxide semiconductor, amorphous silicon, polysilicon, or low-temperature polysilicon (LTPS), but embodiments of the present disclosure are not limited thereto. The first transistor TFT1 may be implemented as a p-channel transistor or an n-channel transistor, but embodiments of the present disclosure are not limited thereto.

The first electrode Ela may be a gate electrode, the second electrode Elb may be a source electrode or a drain electrode, and the third electrode Elc may be a drain electrode or a source electrode. Hereinafter, for convenience of explanation, there is exemplified that the first electrode Ela is a first gate electrode Ela, the second electrode Elb is a first source electrode Elb, and the third electrode Elc is a first drain electrode. However, embodiments of the present disclosure are not limited thereto.

The second transistor TFT2 may include a second active layer ACT2, a fourth electrode E2a, a fifth electrode E2b, and a sixth electrode E2c. The second active layer ACT2 may be a second semiconductor layer, but embodiments of the present disclosure are not limited thereto. For example, the second active layer ACT2 may be made of an oxide semiconductor, amorphous silicon, polysilicon, or low-temperature polysilicon (LTPS), but embodiments of the present disclosure are not limited thereto. The second transistor TFT2 may be implemented as a p-channel transistor or an n-channel transistor, but embodiments of the present disclosure are not limited thereto.

For example, one of the first transistor TFT1 and the second transistor TFT2 may include an oxide semiconductor as an active layer. For another example, one of the first transistor TFT1 and the second transistor TFT2 may include low-temperature polysilicon as an active layer. For another example, the first transistor TFT1 and the second transistor TFT2 may include an oxide semiconductor as an active layer. For another example, the first transistor TFT1 and the second transistor TFT2 may include low-temperature polysilicon as an active layer. For another example, among the first transistor TFT1 and the second transistor TFT2, the driving transistor DT may include an oxide semiconductor as an active layer, and the scan transistor ST may include low-temperature polysilicon as an active layer. For another example, among the first transistor TFT1 and the second transistor TFT2, the driving transistor DT may include low-temperature polysilicon as an active layer, and the scan transistor ST may include an oxide semiconductor as an active layer. For another example, a transistor included in the gate driving circuit 130 of the gate-in-panel (GIP) type may include an oxide semiconductor or low temperature polysilicon as an active layer. For another example, all transistors configured on the substrate 111 and transistors included in the gate driving circuit 130 of the gate-in-panel type may include an oxide semiconductor as an active layer.

The fourth electrode E2a may be a gate electrode, the fifth electrode E2b may be a source electrode or a drain electrode, and the sixth electrode E2c may be a drain electrode or a source electrode. Hereinafter, for convenience of explanation, there is exemplified that the fourth electrode E2a is a second gate electrode E2a, the fifth electrode E2b is a second source electrode E2b, and the sixth electrode E2c is a second drain electrode. However, embodiments of the present disclosure are not limited thereto.

The second active layer ACT2 of the second transistor TFT2 may be located higher from the substrate 111 than the first active layer ACT1 of the first transistor TFT1.

A first buffer layer 311 may be disposed under the first active layer ACT1 of the first transistor TFT1, and a second buffer layer 321 may be disposed under the second active layer ACT2 of the second transistor TFT2. For example, the first active layer ACT1 of the first transistor TFT1 may be located on the first buffer layer 311, and the second active layer ACT2 of the second transistor TFT2 may be located on the second buffer layer 321. The second buffer layer 321 may be located higher than the first buffer layer 311.

The storage capacitor Cst may be disposed in various metal layers within the display panel 110. For example, the storage capacitor Cst may include a first capacitor electrode CAPE1 and a second capacitor CAPE2.

The transistor forming part 300 may further include at least one planarization layer 331 and 332 for planarizing upper portions of the transistors TFT1 and TFT2. The light emitting device forming part may be disposed on at least one planarization layer 331 and 332.

The light emitting device forming part may include a plurality of light emitting devices ED. Each of the plurality of light emitting devices ED may include a pixel electrode PE, an intermediate layer EL, and a common electrode CE.

The encapsulation part may include an encapsulation layer 200 on a plurality of light emitting devices ED. The encapsulation layer 200 may be a single layer or multiple layers. The encapsulation part may further include a dam DAM in addition to the encapsulation layer 200.

Hereinafter, it will be described a vertical structure of the display panel 110 according to embodiments of the present disclosure in more detail with reference to FIG. 3.

Referring to FIG. 3, the first buffer layer 311 may be disposed on the substrate 111. The first buffer layer 311 may be a single layer or multiple layers. When the first buffer layer 311 is a multiple layer, the first buffer layer 311 may include a multi-buffer layer 311a and an active buffer layer 311b.

The first active layer ACT1 of the first transistor TFT1 may be disposed on the first buffer layer 311. The first active layer ACT1 may include a channel region where a channel is formed, a source connection region on one side of the channel region, and a drain connection region on the other side of the channel region.

A first gate insulating layer 312 may be disposed on the first active layer ACT1 of the first transistor TFT1. The first gate electrode Ela of the first transistor TFT1 may be disposed on the first gate insulating layer 312. A first interlayer insulating layer 313 may be disposed on the first gate electrode Ela of the first transistor TFT1.

The second buffer layer 321 may be disposed on the first interlayer insulating layer 313.

The second active layer ACT2 of the second transistor TFT2 may be disposed on the second buffer layer 321. The second active layer ACT2 may include a channel region where a channel is formed, a source connection region on one side of the channel region, and a drain connection region on the other side of the channel region.

A second gate insulating layer 322 may be disposed on the second active layer ACT2 of the second transistor TFT2. The second gate electrode E2a of the second transistor TFT2 may be disposed on the second gate insulating layer 322. A second interlayer insulating layer 323 may be disposed on the second gate electrode E2a of the second transistor TFT2.

The first source electrode E1b and the first drain electrode Elc of the first transistor TFT1, and the second source electrode E2b and the second drain electrode E2c of the second transistor TFT2 may be disposed on the second interlayer insulating layer 323.

The first source electrode E1b and the first drain electrode Elc of the first transistor TFT1 may be connected to the source connection region and the drain connection region of the first active layer ACT1, respectively, through a holes in the second interlayer insulating layer 323, the second gate insulating layer 322, the second buffer layer 321, the first interlayer insulating layer 313, and the first gate insulating layer 312.

The second source electrode E2b and the second drain electrode E2c of the second transistor TFT2 may be connected to the source connection region and the drain connection region of the second active layer ACT2, respectively, through a hole in the second interlayer insulating layer 323 and the second gate insulating layer 322.

The first source electrode E1b and the first drain electrode Elc of the first transistor TFT1, and the second source electrode E2b and the second drain electrode E2c of the second transistor TFT2 may include a first metal, and may be disposed within the first metal layer. Here, the first metal and the first metal layer may be referred to as a first source-drain metal and a first source-drain metal layer.

Referring to FIG. 3, as an example, the storage capacitor Cst may be formed by a first capacitor electrode CAPE1 and a second capacitor electrode CAPE2. In some cases, the storage capacitor Cst may be formed by three or more capacitor electrodes, or may be formed by two or more capacitors connected in parallel.

Each of the first capacitor electrode CAPE1 and the second capacitor electrode CAPE2 may be disposed on various metal layers disposed within the display panel 110.

For example, the first capacitor electrode CAPE1 may include the same first gate metal as the first gate electrode Ela of the first transistor TFT1 on the first gate insulating layer 312, and may be disposed within a first gate metal layer.

For example, the second capacitor electrode CAPE2 may be disposed on the first interlayer insulating layer 313.

The second source electrode E2b of the second transistor TFT2 may be electrically connected to the second capacitor electrode CAPE2 through holes in the second interlayer insulating layer 323, the second gate insulating layer 322, and the second buffer layer 321.

For example, the first transistor TFT1 may be the scan transistor ST of FIG. 2, and the second transistor TFT2 may be the driving transistor DT of FIG. 2.

The transistor forming part 300 may further include various metal layers. For example, a first metal layer may be disposed between a multi-buffer layer 311a and an active buffer layer 311b included in the first buffer layer 311. A second metal layer may include the same first gate metal as the first gate electrode Ela of the first transistor TFT1 and may be disposed within the first gate metal layer. The first metal layer may be a first metal pattern, and the second metal layer may be a second metal pattern, but embodiments of the present disclosure are not limited thereto.

Each of the first metal layer and the second metal layer may be disposed in the display area DA or the non-display area NDA.

Referring to FIG. 3, the transistor forming part 300 may further include a first shield metal BSM1 which is disposed on the substrate 111, overlaps with the first active layer ACT1 of the first transistor TFT1, and is disposed below the first active layer ACT1 of the first transistor TFT1. For example, the first shield metal BSM1 may be disposed between the substrate 111 and the first buffer layer 311, or may be disposed between the multi-buffer layer 311a and the active buffer layer 311b.

The transistor forming part 300 may further include a second shield metal BSM2 which is disposed on the substrate 111, overlaps with the second active layer ACT2 of the second transistor TFT2, and is disposed below the second active layer ACT2 of the second transistor TFT2.

For example, the second shield metal BSM2 may be disposed in a metal layer between the first interlayer insulating layer 313 and the second buffer layer 321. The second shield metal BSM2 may be disposed in the same metal layer as the second capacitor CAPE2.

For another example, the second shield metal BSM2 may be disposed in the same first gate metal layer as the first gate electrode Ela of the first transistor TFT1. Referring to FIG. 3, the transistor forming part 300 may further include a common driving voltage pattern to which a common driving voltage is applied. For example, the common driving voltage applied to the common driving voltage pattern may be referred to as a power signal, and may be a first common driving voltage VDD or a second common driving voltage VSS. The first common driving voltage VDD may be referred to as a high-potential power supply voltage (e.g., high-potential power signal), and the second common driving voltage VSS may be referred to as a low-potential power supply voltage (e.g., low-potential power signal) or a base voltage. The common driving voltage pattern may be disposed in the display area DA or the non-display area NDA.

In the transistor forming part 300, at least one planarization layer 331 or 332 may be disposed on the first transistor TFT1 and the second transistor TFT2. The example of FIG. 3 is a case where two planarization layers 331 and 332 are disposed on the first transistor TFT) and the second transistor TFT2. In some cases, three or more planarization layers may be disposed on the first transistor TFT1 and the second transistor TFT2, but embodiments of the present disclosure are not limited thereto.

Referring to FIG. 3, the first planarization layer 331 may be disposed on the first source electrode E1b and the first drain electrode Elc of the first transistor TFT1, and the second electrode source electrode E2b and the second drain electrode E2c of the second transistor TFT2. For example, the first planarization layer 331 may be disposed to cover both the first transistor TFT1 and the second transistor TFT2.

Referring to FIG. 3, a relay electrode RE may be disposed on the first planarization layer 331. The relay electrode RE may be electrically connected to the second source electrode E2b of the second transistor TFT2 through a hole in the first planarization layer 331. Here, the second source electrode E2b of the second transistor TFT2 may be electrically connected to the second capacitor electrode CAPE2 of the storage capacitor Cst.

The relay electrode RE may be disposed in a second metal layer on the first planarization layer 331, and may include a second metal. The second metal and the second metal layer may be referred to as a second source-drain metal and a second source-drain metal layer.

The second planarization layer 332 may be disposed on the relay electrode RE.

Referring to FIG. 3, the light emitting device forming part may be disposed on the second planarization layer 332. The light emitting device ED may be formed on the second planarization layer 332. The light emitting device ED may include a pixel electrode PE, an intermediate layer EL, and a common electrode CE. The light emission area of the light emitting device ED may be formed in an area where the pixel electrode PE, the intermediate layer EL, and the common electrode CE overlap and contact each other.

The pixel electrode PE may be disposed on the second planarization layer 332, and a bank 333 may be disposed on the pixel electrode PE. An opening of the bank 333 may expose a portion of the pixel electrode PE to form the emission area. For example, the opening of the bank 333 may overlap with a portion of the pixel electrode PE.

The intermediate layer EL of the light emitting device ED may be disposed on a portion of the pixel electrode PE and the bank 333. The common electrode CE may be disposed on the intermediate layer EL.

Referring to FIG. 3, the encapsulation part may be disposed on the light emitting device forming part, and may be disposed on the common electrode CE. The encapsulation part may include an encapsulation layer 200 formed on the common electrode CE.

The encapsulation layer 200 may prevent moisture or oxygen from penetrating into the light emitting device ED. For example, the encapsulation layer 200 may prevent moisture or oxygen from penetrating into organic matter contained in the intermediate layer EL of the light emitting device ED. Here, the encapsulation layer 200 may be composed of a single layer or multiple layers, but embodiments of the present disclosure are not limited thereto.

Referring to FIG. 3, as an example, the encapsulation layer 200 may include a first inorganic layer 341, an organic layer 342, and a second inorganic layer 343.

The display panel 110 according to embodiments of the present disclosure may have a built-in touch sensor. In this case, the display panel 110 according to embodiments of the present disclosure may include a touch sensor layer 210 formed on the encapsulation layer 200.

Referring to FIG. 3, the touch sensor layer 210 may include a plurality of touch electrodes TE, and may include a sensor metal TSM and a bridge metal BRG to form the plurality of touch electrodes TE. In an embodiment of the present disclosure, the sensor metal TSM may be also referred to as a sensor metal layer TSM, and the bridge metal BRG may be also referred to as a bridge metal layer BRG.

The touch sensor layer 210 may further include insulating layers such as a sensor buffer layer 351 on the encapsulation layer 200, a sensor interlayer insulating layer 352 on the sensor buffer layer 351, and a sensor protection layer 353 on the sensor interlayer insulating layer 352. Here, the sensor buffer layer 351 may be omitted.

The bridge metal BRG may be disposed between the sensor buffer layer 351 and the sensor interlayer insulating layer 352, and the sensor metal TSM may be disposed between the sensor interlayer insulating layer 352 and the sensor protection layer 353.

Each of the plurality of touch electrodes TE may be composed of sensor metal TSM. Each of the plurality of touch electrodes TE may be a mesh-type electrode having a plurality of openings.

The plurality of touch electrodes TE may include a first touch electrode TE1 and a second touch electrode TE2. The sensor metals TSM included in the first touch electrode TE1 may be electrically connected through the bridge metal BRG. That is, the sensor metal TSM spaced apart from each other may be electrically connected by the bridge metal BRG to form one first touch electrode TE1.

The bridge metal BRG may be disposed on the sensor buffer layer 351, and the sensor interlayer insulating layer 352 may be disposed on the bridge layers BRG. The sensor metal TSM may be disposed on the sensor interlayer insulating layer 352. A portion of the sensor metal TSM may be connected to the corresponding bridge metal BRG through a hole in the sensor interlayer insulating layer 352.

Referring to FIG. 3, the sensor metal TSM and bridge metal BRG may be arranged so as not to overlap with the light emitting device ED. The sensor metal TSM and bridge metal BRG may overlap with the bank 333.

A plurality of sensor metals TSM may form one touch electrode TE, and may be arranged in a mesh form and electrically connected. A part of the sensor metal TSM and another part of the sensor metal TSM may be electrically connected through a bridge metal BRG to form one touch electrode TE.

The sensor protection layer 353 may be disposed while covering the sensor metal TSM and bridge metal BRG.

A touch line (e.g., TL in FIG. 2) may electrically connect the touch electrode TE and a touch pad TP. The touch line may be composed of at least one of sensor metal TSM and bridge metal BRG.

The touch line may extend along the outer slope of the encapsulation layer 200, and may extend to the touch pad (e.g., TP in FIG. 2) of the pad area in the non-display area NDA. Here, the outer slope of the encapsulation layer 200 may exist in the non-display area NDA.

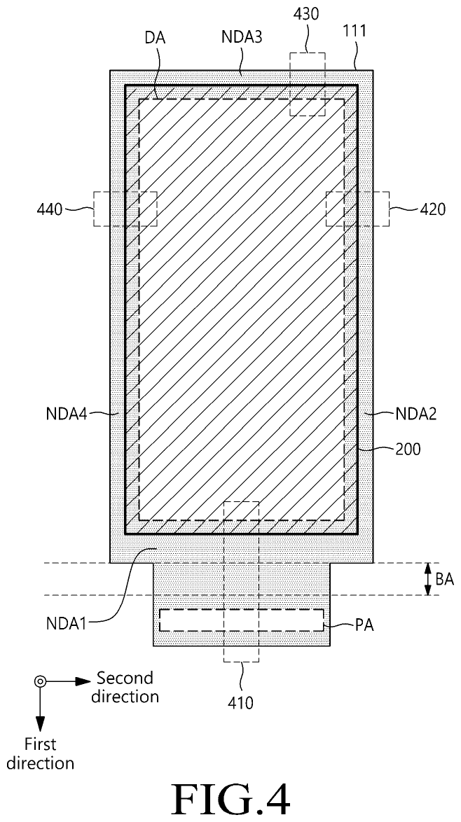

FIG. 4 is a plan view of a display panel 110 according to embodiments of the present disclosure.

Referring to FIG. 4, the substrate 111 of the display panel 110 according to embodiments of the present disclosure may include a display area DA in which an image is displayed and a non-display area NDA in which an image is not displayed.

Referring to FIG. 4, the non-display area NDA may include a first non-display area NDA1 located in a first direction from the display area DA, a second non-display area NDA2 located in a second direction from the display area DA, a third non-display area NDA3 located in a direction opposite to the first direction from the display area DA, and a fourth non-display area NDA4 located in a direction opposite to the second direction from the display area DA. For example, the first direction may be a column direction (e.g., Y-axis direction), and the second direction crossing the first direction may be a row direction (e.g., X-axis direction).

The first non-display area NDA1 may include a pad area PA where a plurality of pads is disposed. In the pad area PA, there may be disposed a plurality of pads to which the driving circuit is electrically connected. A plurality of driving circuits or printed circuit boards may be electrically connected. For example, the plurality of pads may include a plurality of display pads and a plurality of touch pads. A plurality of data lines, a first common driving voltage line VDDL, a second common driving voltage line VSSL may be electrically connected to the plurality of display pads. A plurality of touch routing lines TL may be electrically connected to the plurality of touch pads.

The first non-display area NDA1 may further include a bending area BA. In this case, the substrate 111 may be a flexible substrate. In some cases, the first non-display area NDA1 may not include the bending area BA.

The display panel 110 may further include a ground line disposed in the non-display area NDA of the substrate 111. The ground line may be disposed from one point in the pad area PA to another point in the pad area PA via the second non-display area NDA2, the third non-display area NDA3, and the fourth non-display area NDA4.

In the display panel 110 according to embodiments of the present disclosure, the encapsulation layer 200 may have a structure in which an inorganic layer and an organic layer are stacked. In this case, an edge of the encapsulation layer 200 may be regarded as an edge of the organic layer.

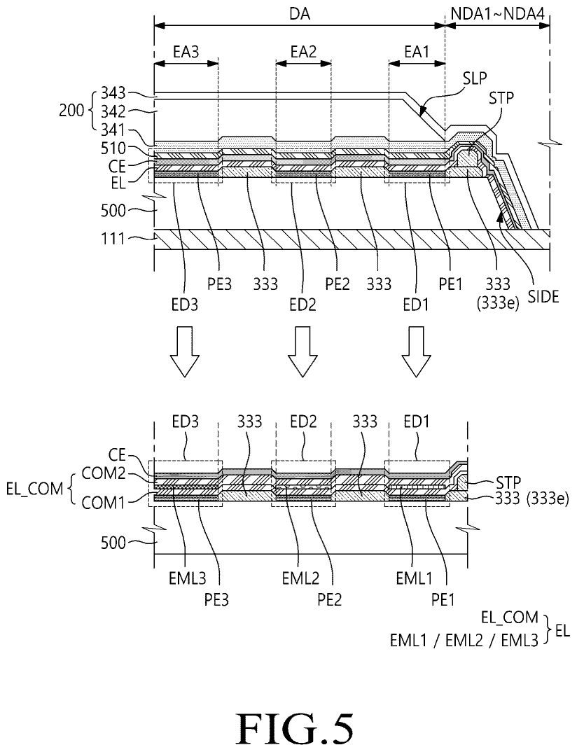

Hereinafter, it will be described a vertical structure of an outer area with reference to FIG. 5.

FIG. 5 is a cross-sectional view of an outer area of a display panel 110 according to embodiments of the present disclosure.

Referring to FIG. 5, the display panel 110 according to embodiments of the present disclosure may include a substrate 111, an insulating layer 500 on the substrate 111, a plurality of light emitting devices ED1, ED2 and ED3, and an encapsulation layer 200 on a plurality of light emitting devices ED1, ED2 and ED3. Here, the insulating layer 500 may include at least one insulating layer, and may be included in the transistor forming part 300 of FIG. 3.

The encapsulation layer 200 may include a first inorganic layer 341, an organic layer 342, and a second inorganic layer 343. The organic layer 342 may be disposed between the first inorganic layer 341 and the second inorganic layer 342.

The insulating layer 500 may include a plurality of insulating layers located between the substrate 111 and the plurality of light emitting devices ED1, ED2 and ED3. The plurality of insulating layers may include at least one planarization layer.

The insulating layer 500 may include a plurality of insulating layers necessary to form transistors. The insulating layer 500 may include an organic insulating layer stack including at least one organic insulating layer, and an inorganic insulating layer stack including at least one inorganic insulating layer. For example, the organic insulating layer stack may include at least one planarization layer, the inorganic insulating layer stack may include at least one buffer layer, at least one gate insulating layer, or at least one interlayer insulating layer, etc.

The insulating layer 500 may be located on the substrate 111, and may have a side SIDE in the non-display area NDA.

In order to form a plurality of light emitting devices ED1, ED2 and ED3 on the insulating layer 500, the display panel 110 may include a bank 333 located on the insulating layer 500 as a subpixel defining layer for dividing a plurality of emission areas EA1, EA2 and EA3 and having a plurality of openings (e.g., bank holes), a plurality of pixel electrodes PE1, PE2 and PE3 located on the insulating layer 500 and at least partially overlapping with a plurality of openings (e.g., bank holes) of the bank 333, a plurality of emission layers EML1, EML2 and EML3 located on a plurality of pixel electrodes PE1, PE2 and PE3, and a common electrode CE located on the plurality of emission layers EML1, EML2 and EML3 and extending from the display area DA to a portion of the non-display area NDA.

The plurality of pixel electrodes PE1, PE2 and PE3, the plurality of emission layers EML1, EML2 and EML3, and the common electrode CE may overlap to form a plurality of light emitting devices ED1, ED2 and ED3.

Referring to FIG. 5, the display panel 110 according to embodiments of the present disclosure may include a stopper STP as a structure (e.g., organic layer overflow prevention structure) to prevent overflow of the organic layer 342 included in the encapsulation layer 200.

Referring to FIG. 5, the stopper STP may be not only an organic layer overflow prevention structure but also one of the extreme narrow bezel structures. That is, the stopper STP may serve to prevent overflow of the organic layer 342 and reduce the non-display area NDA.

The stopper STP may be disposed in the non-display area NDA, and may be disposed in a ring shape surrounding the periphery of the organic layer 342. The stopper STP may be located between the display area DA and the pad area PA.

The stopper STP may be located on the insulating layer 500, and may be located further outside the organic layer 342. For example, as shown in FIG. 5, the stopper STP may be located on the outermost part 333e of the bank 333. As another example, the outermost part 333e of the bank 333 may be part included in the stopper STP, and in this case, the stopper STP may be disposed further outside the bank 333.

The common electrode CE may be located on the insulating layer 500 and extend from the display area DA to a portion of the non-display area NDA, and may overlap with at least a portion of an upper surface of the stopper STP.

The stopper STP may be disposed further outside a first light emitting device ED1 which is the outermost light emitting device ED among the plurality of light emitting devices ED1, ED2 and ED3. The stopper STP may be disposed on the outer side of the first light emitting device ED1 which is the outermost light emitting device ED.

The stopper STP may include organic material.

The stopper STP may have a thickness greater than that of the first pixel electrode PE1 of the first light emitting device ED1 which is the outermost light emitting device ED1. For example, the stopper STP may have a thickness greater than the sum of the thicknesses of the first pixel electrode PE1, the intermediate layer EL and the common electrode CE of the first light emitting device ED1 which is the outermost light emitting device ED. The intermediate layer EL of the first light emitting device ED1, which is the outermost light emitting device ED1, may include a first common intermediate layer COM1, a first emission layer EML1, and a second common intermediate layer COM2.

For example, the highest upper surface of the stopper STP may be located higher than the upper surface of the common electrode CE in the emission areas EA1, EA2 and EA3. Accordingly, the common electrode CE may be disposed along the inner surface of the stopper STP, and extend upward to the upper portion of the stopper STP.

Since the display panel 110 is provided with a stopper STP, it is not required to form a dam structure which requires a large formation area to prevent overflow of the organic layer 342. In addition, since the stopper STP is formed above the outermost part 333e of the bank 333, the size of the non-display area NDA may not increase.

Referring to FIG. 5, for example, the plurality of light emitting devices ED1, ED2 and ED3 may include a first light emitting device ED1 located in a first emission area EA1, a second light emitting device ED2 located in a second emission area EA2, and a third light emitting device ED3 located in a third emission area EA3.

The first light emitting device ED1 may include a first pixel electrode PE1, an intermediate layer EL, and a common electrode CE, and the intermediate layer EL of the first light emitting device ED1 may include a first common intermediate layer COM1, a first emission layer EML1, and a second common intermediate layer COM2.

The second light emitting device ED2 may include a second pixel electrode PE2, an intermediate layer EL, and a common electrode CE, and the intermediate layer EL of the second light emitting device ED2 may include a first common intermediate layer COM1, a second emission layer EML2, and a second common intermediate layer COM2.

The third light emitting device ED3 may include a third pixel electrode PE3, an intermediate layer EL, and a common electrode CE, and the intermediate layer EL of the third light emitting device ED3 may include a first common intermediate layer COM1, a third emission layer EML3, and a second common intermediate layer COM2.

The first pixel electrode PE1, the second pixel electrode PE2, and the third pixel electrode PE3 may be disposed on the first emission area EA1, the second emission area EA2, and the third emission area EA3, respectively.

The first emission layer EML1, the second emission layer EML2, and the third emission layer EML3 may be respectively disposed in the first emission area EA1, the second emission area EA2, and the third emission area EA3.

The common intermediate layer EL_COM including the first common intermediate layer COM1 and the second common intermediate layer COM2 and the common electrode CE may be disposed throughout the display area DA, and may extend from the display area DA to at least a portion of the non-display area NDA.

The first inorganic layer 341 may be located on the common electrode CE, and may be disposed to extend from the display area DA to the non-display area NDA. The organic layer 342 may be located on a portion of the first inorganic layer 341, and may have an outer slope SLP. The second inorganic layer 343 may be located on the organic layer 342, and may be disposed to extend from the display area DA to the non-display area NDA, and may be disposed to extend along the outer slope SLP of the organic layer 342.

The first inorganic layer 341 may extend to the side SIDE of the insulating layer 500 along an upper portion and an outer side of the stopper STP. The second inorganic layer 343 may extend to the outside of the outer slope SLP of the organic layer 342, and may be located on the first inorganic layer 341 extending to the side SIDE of the insulating layer 500 along the upper and outside of the stopper STP.

The bank 333 may be located on the insulating layer 500, and may have first to third openings (e.g., first to third bank holes) for defining or forming the first to third emission areas EA1, EA2 and EA3. The first to third openings (e.g., first to third bank holes) may correspond to the first to third emission areas EA1, EA2 and EA3.

The first to third pixel electrodes PE1, PE2 and PE3 may be located on the insulating layer 500, and at least a portion of each of the first to third pixel electrodes PE1, PE2 and PE3 may overlap with the first to third openings (e.g., first to third bank holes) of the bank 333, respectively.

The first common intermediate layer COM1 may be commonly disposed on the first to third pixel electrodes PE1, PE2 and PE3, and may also be disposed on the bank 333.

The first to third emission layers EML1, EML2 and EML3 may be located on the first common intermediate layer COM1, and may overlap with the first to third pixel electrodes PE1, PE2 and PE3. The first to third emission layers EML1, EML2 and EML3 may correspond to the first to third emission areas EA1, EA2 and EA3.

The second common intermediate layer COM2 may be commonly disposed on the first to third emission layers EML1, EML2 and EML3, and may also be disposed on the bank 333.

The common intermediate layer EL_COM including the first common intermediate layer COM1 and the second common intermediate layer COM2 may exist on the bank 333. The common intermediate layer EL_COM may be disposed throughout the display area DA. Each of the first common intermediate layer COM1 and the second common intermediate layer COM2 may include an organic material. The common electrode CE may be located on the second common intermediate layer COM2.

The common intermediate layer EL_COM and the common electrode CE may extend to the upper portion of the stopper STP, and accordingly, the common intermediate layer EL_COM and the common electrode CE may be overlap with at least a portion of the stopper STP. For example, the common intermediate layer EL_COM and the common electrode CE may extend to the upper portion and outer side of the stopper STP. If the common intermediate layer EL_COM and the common electrode CE further extend, the common intermediate layer EL_COM and the common electrode CE may pass through the upper and outer sides of the stopper STP and extend to the side SIDE of the insulating layer 500.

The display panel 110 may further include a capping layer 510 located between the common electrode CE and the first inorganic layer 341 and extending from the display area DA to the non-display area NDA. The capping layer 510 may extend to the side SIDE of the insulating layer 500 along the upper and outer side of the stopper STP.

The common intermediate layer EL_COM, the common electrode CE, and the capping layer 510 may be disposed on the side SIDE of the insulating layer 500.

The stopper STP may be disposed on the outer side of the first light emitting device ED1 which is the outermost light emitting device ED among the plurality of light emitting devices ED1, ED2 and ED3 corresponding to the plurality of subpixels SP, and may have a thickness greater than that of the first pixel electrode PE1 of the first light emitting device ED1.

A lower surface bottom of the stopper STP may have a larger area than a upper surface of the outermost part 333e of the bank 333. The stopper STP may include the same material (e.g., spacer material) as the spacer on the bank 333. The bank material and/or the spacer material may be the same material or may be different materials. The bank material and/or the spacer material may include organic materials.

For example, each of the first inorganic layer 341 and the second inorganic layer 342 may be made of silicon nitride, aluminum nitride, zirconium nitride, titanium nitride, hafnium nitride, tantalum nitride, silicon oxide, aluminum oxide, or titanium oxide. However, this is only an example and is not limited thereto.

For example, the organic layer 342 may be formed of acryl resin, epoxy resin, phenolic resin, or polyimide resin. The organic layer 342 may be formed by being applied in liquid form through an inkjet process and then through a curing process. This is only an example and is not limited thereto.

As described above, the display device 100 according to embodiments of the present disclosure may include a stopper STP as a structure capable of preventing the overflow of the organic layer 342 while reducing the bezel size.

The display device 100 according to embodiments of the present disclosure may further include a “blocking pattern layer” as an additional structure capable of more effectively preventing overflow of the organic layer 342 while reducing the bezel size. Hereinafter, it will be described a blocking pattern layer of the display device 100 according to embodiments of the present disclosure.

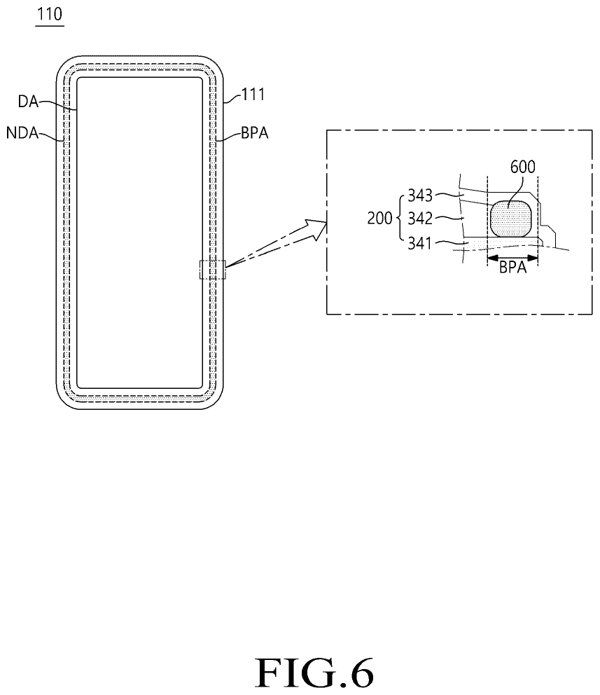

FIG. 6 is a plan view of a display panel 110 according to embodiments of the present disclosure, including a blocking pattern area BPA and a blocking pattern layer 600 disposed thereon.

Referring to FIG. 6, the display panel 110 according to embodiments of the present disclosure may include a blocking pattern area BPA which may prevent overflow of the organic layer 342. The blocking pattern area BPA may be included in the non-display area NDA, and may be located surrounding the display area DA.

Referring to FIG. 6, the display panel 110 according to embodiments of the present disclosure may include a blocking pattern layer 600 disposed in the blocking pattern area BPA.

The blocking pattern layer 600 may be disposed in relation to the encapsulation layer 200 including the first inorganic layer 341, the organic layer 342, and the second inorganic layer 343.

The blocking pattern layer 600 may be disposed within the encapsulation layer 200.

The blocking pattern layer 600 may be disposed on the first inorganic layer 341, and may be disposed on the side of the organic layer 342. The blocking pattern layer 600 may be disposed between the first inorganic layer 341 and the second inorganic layer 343. The second inorganic layer 343 may be disposed on the upper and outer sides of the blocking pattern layer 600.

An inner surface of the blocking pattern layer 600 may be formed with round curved surfaces.

Since the inner surface of the blocking pattern layer 600 is formed with round curved surfaces, the flow of the organic layer 342 included in the encapsulation layer 200 may be further slowed during the formation process. Accordingly, there may be effectively prevented the overflow of the organic layer 342 included in the encapsulation layer 200.

As an example, the blocking pattern layer 600 may include one pattern layer.

As another example, the blocking pattern layer 600 may include two or more pattern layers.

In the case that the blocking pattern layer 600 includes two or more pattern layers, the two or more pattern layers may be stacked vertically or horizontally. That is, the blocking pattern area BPA may include a vertically stacked blocking pattern layer 600 or a horizontally stacked blocking pattern layer 600.

Hereinafter, it will be described a vertically stacked blocking pattern layer 600 in more detail, and then it will be described a horizontally stacked blocking pattern layer 600 in more detail.

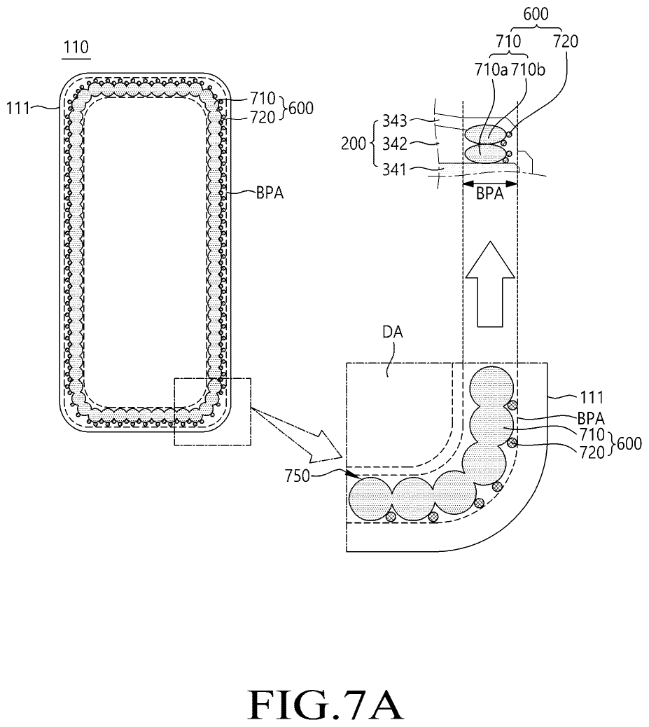

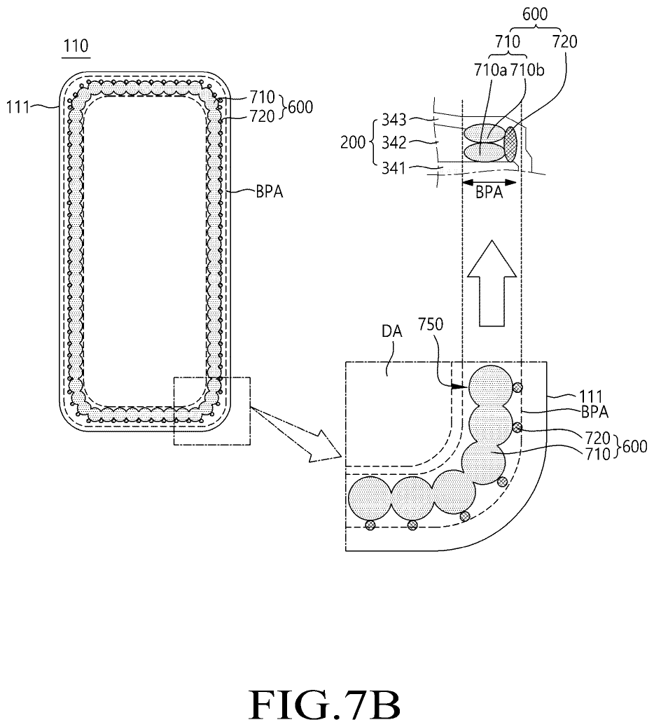

FIGS. 7A and 7B are plan views of a display panel 100 according to embodiments of the present disclosure, and illustrate a display panel including a vertically stacked blocking pattern layer 600.

Referring to FIGS. 7A and 7B, the display panel 110 according to embodiments of the present disclosure may include a blocking pattern layer 600 disposed on a blocking pattern area BPA defined to prevent overflow of the organic layer 342 included in the encapsulation layer 200.

Referring to FIGS. 7A and 7B, the blocking pattern layer 600 may be disposed in the non-display area NDA, and may be located surrounding the display area DA.

Referring to FIGS. 7A and 7B, an inorganic pattern layer 710 may be formed by connecting patterns having a circular or oval shape. An inner surface of the inorganic pattern layer 710 may be formed by connecting round curved surfaces 750.

Referring to FIGS. 7A and 7B, since the inner surface of the inorganic pattern layer 710 is formed as a round curved surface 750, the flow of the organic layer 342 may be slower in the process of forming the organic layer 342 included in the encapsulation layer 200. Accordingly, there may be effectively prevented the overflow of the organic layer 342 included in the encapsulation layer 200.

Referring to FIGS. 7A and 7B, an organic pattern layer 720 may block moisture. To this end, the organic pattern layer 720 may include a getter.

Referring to FIGS. 7A and 7B, in the case that the blocking pattern layer 600 is vertically stacked, the blocking pattern layer 600 may include the inorganic pattern layer 710 on the first inorganic layer 341, and the organic pattern layer 720 disposed on the outer side of the inorganic pattern layer 710.

Referring to FIGS. 7A and 7B, the inorganic pattern layer 710 may prevent the organic layer 600 from overflowing. Since the inorganic pattern layer 710 is disposed on the first inorganic layer 341 to control the flow of the organic layer 600, it is possible to prevent overflow of the organic layer 600 while enabling a narrow bezel.

Referring to FIGS. 7A and 7B, the inorganic pattern layer 710 may block moisture. That is, the inorganic pattern layer 710 may be a moisture barrier.

Referring to FIGS. 7A and 7B, the inorganic pattern layer 710 may include a first inorganic pattern layer 710a on the first inorganic layer 341 and a second inorganic pattern layer 710b on the first inorganic pattern layer 710a.

Referring to FIG. 7A, the organic pattern layer 720 may be disposed on the outer side of the inorganic pattern layer 710, and may include at least one fine organic pattern in the form of particles.

One fine organic pattern included in the organic pattern layer 720 may have a size smaller than each of the first inorganic pattern layer 710a and the second inorganic pattern layer 710b.

Referring to FIG. 7B, the organic pattern layer 720 may be disposed on the outer side of the inorganic pattern layer 710. As an example, a height of the organic pattern layer 720 may correspond to the sum of a heights of the first inorganic pattern layer 710a and a height of the second inorganic pattern layer 710b. As another example, a height of the organic pattern layer 720 may be less than the sum of a height of the first inorganic pattern layer 710a and a height of the second inorganic pattern layer 710b. As another example, a height of the organic pattern layer 720 may exceed the sum of the heights of the first inorganic pattern layer 710a and the second inorganic pattern layer 710b.

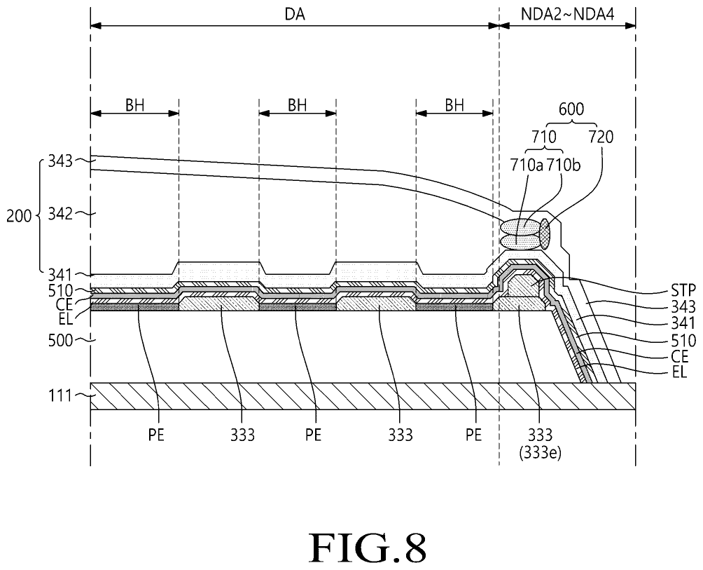

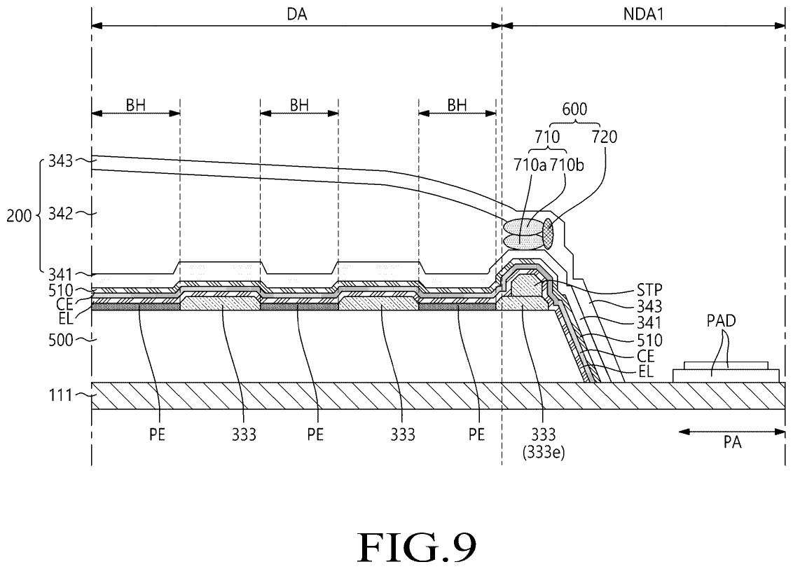

FIGS. 8 and 9 are cross-sectional views of a display panel 110 according to embodiments of the present disclosure, and illustrate cross-sectional views of a display panel 110 including a vertically stacked blocking pattern layer 600.

Referring to FIGS. 8 and 9, the display panel 110 according to embodiments of the present disclosure may include a substrate 111 including a display area DA and non-display areas NDA1 to NDA4, an insulating layer 500 located on the substrate 111, and a bank 333 located on the insulating layer 500 and having a bank hole BH.

Referring to FIGS. 8 and 9, the display panel 110 according to embodiments of the present disclosure may include a first inorganic layer 341 located on the bank 333, a blocking pattern layer 600 located on the first inorganic layer 341, an organic layer 342 located on the first inorganic layer 341 and disposed on the inner surface of the blocking pattern layer 600, and a second inorganic layer 343 located on the organic layer 342 and extending to the top of the blocking pattern layer 600.

Referring to FIGS. 8 and 9, the blocking pattern layer 600 may be located on the first inorganic layer 341, and may be disposed on the side of the organic layer 342.

Referring to FIGS. 8 and 9, the blocking pattern layer 600 may be located on the first inorganic layer 341, and may be located on an edge portion 333e, which is the outermost portion of the bank 333. The blocking pattern layer 600 may overlap with at least a portion of the edge portion 333e of the bank 333.

Referring to FIGS. 8 and 9, in the display panel 110 according to embodiments of the present disclosure, a light emitting device forming part may be disposed on the insulating layer 500. The light emitting device forming part may include a plurality of light emitting devices ED, and may include a plurality of pixel electrodes PE, an intermediate layer EL, and a common electrode CE to configure the plurality of light emitting devices ED.

Referring to FIGS. 8 and 9, the display panel 110 according to embodiments of the present disclosure may further include a pixel electrode PE on the insulating layer 500, an intermediate layer EL on the pixel electrode PE, and a common electrode CE on the intermediate layer EL. The first inorganic layer 341 may be located on the common electrode CE.

Referring to FIGS. 8 and 9, the bank 300 may expose at least a portion of the pixel electrode PE while covering at least one or both ends of the pixel electrode PE. The bank 300 may include a bank hole BH to expose at least a portion of the pixel electrode PE. The bank hole BH of the bank 300 may overlap with at least a portion of the pixel electrode PE.

Referring to FIGS. 8 and 9, the intermediate layer EL and the common electrode CE may extend along the side of the insulating layer 500 past an upper of the edge portion 333e of the bank 333, and may also be disposed in at least portion of the non-display areas NDA1 to NDA4.

Referring to FIGS. 8 and 9, since the blocking pattern layer 600 is located on the edge portion 333e of the bank 333, the blocking pattern layer 600 may be disposed further outside the outermost light emitting device (or outermost emission area) among the light emitting devices (or emission areas).

Referring to FIGS. 8 and 9, the stopper STP may be located between the edge portion 333e of the bank 333 and the first inorganic layer 341. The overflow of the organic layer 342 may be prevented by using a stopper STP.

Referring to FIGS. 8 and 9, the first inorganic layer 341 may be disposed in the display area DA, may extend along the side of the insulating layer 500 past the upper part of the edge portion 333e of the bank 333, and may also be disposed in at least portion of the non-display area NDA.

Referring to FIGS. 8 and 9, the second inorganic layer 343 may be disposed in the display area DA, may extend to the non-display area NDA past an upper part of the blocking pattern layer 600. The second inorganic layer 343 may be disposed in the display area DA, may further extend to the outer side of the blocking pattern layer 600 past the upper part of the blocking pattern layer 600, and may be also disposed in at least a portion of the non-display area NDA.

Referring to FIGS. 8 and 9, the capping layer 510 may be located between the common electrode CE and the first inorganic layer 341, and may disposed to extend from the display area DA to the non-display area NDA. The capping layer 510 may extend to the side of the insulating layer 500 along the top and outer side of the stopper STP. The common intermediate layer EL_COM of the intermediate layer EL, a common electrode CE, and a capping layer 510 may be disposed on the side of the insulating layer 500.

Referring to FIG. 8, the second to fourth non-display areas NDA2 to NDA4 may not include the pad area PA. Referring to FIG. 9, the first non-display area NDA1 may further include a pad area PA in which a pad PAD is disposed.

Referring to FIGS. 8 and 9, the encapsulation layer 200 and the blocking pattern layer 600 in the first non-display area NDA1 may have the same structure as the encapsulation layer 200 and the blocking pattern layer 600 are in the second to fourth non-display areas NDA2 to NDA4.

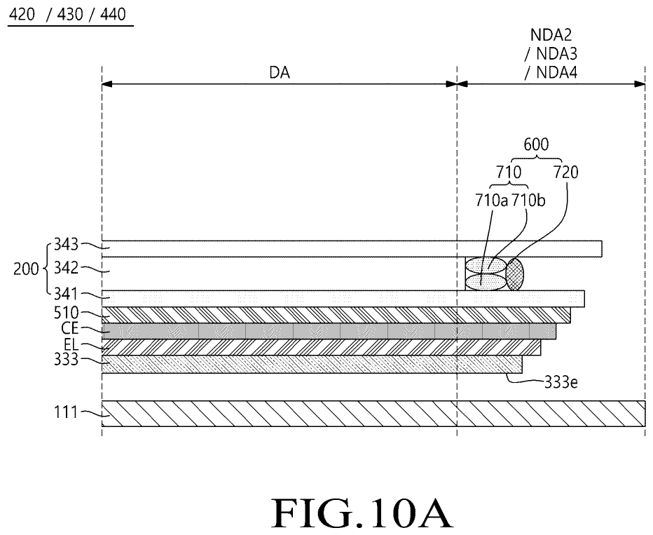

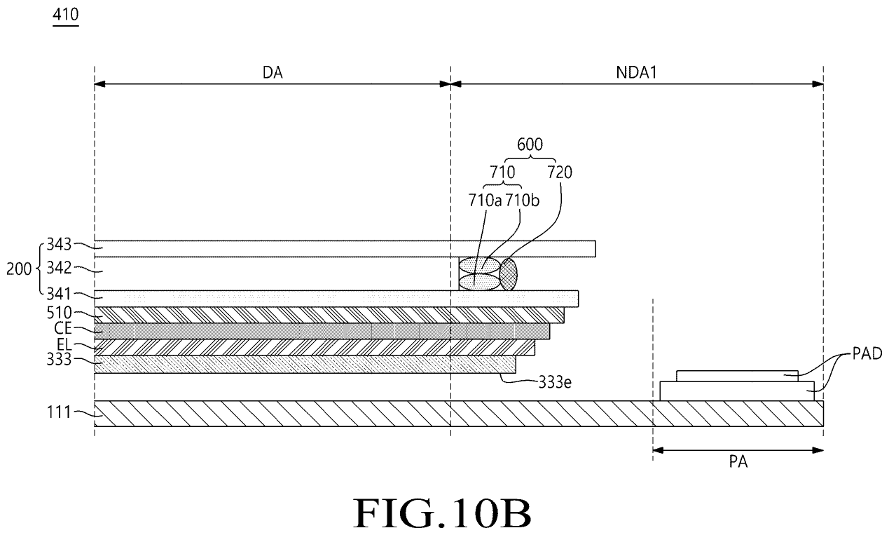

FIGS. 10A and 10B illustrate end positions of main layers (e.g., 333, EL, CE, 800, 341, 342, 343) of a display panel 100 according to embodiments of the present disclosure.

Referring to FIGS. 10A and 10B, the intermediate layer EL may be located on the bank 333, the common electrode CE may be located on the intermediate layer EL, the capping layer 510 may be located on the common electrode CE, the encapsulation layer 200 including the first inorganic layer 341, the organic layer 342, and the second inorganic layer 343 may be located on the capping layer 510.

Referring to FIGS. 10A and 10B, the blocking pattern layer 600 may be disposed on the side of the organic layer 342. The blocking pattern layer 600 may be located on the edge portion 333e of the bank 333.

Referring to FIGS. 10A and 10B, the intermediate layer EL, the common electrode CE, the capping layer 510, and the first inorganic layer 341 may extend along the upper part and the outer side of the edge portion 333e of the bank 333, and may further extend along the outer side of the insulating layer 510 located below the bank 333.

Therefore, an end of the intermediate layer EL may be located further outside an end of the bank 333, an end of the common electrode CE may be located further outside than an end of the intermediate layer EL. In addition, an end of the capping layer 510 may be located further outside than the end of the common electrode CE, and the end of the first inorganic layer 341 may be located further outside than the end of the capping layer 510.

Referring to FIGS. 10A and 10B, the second inorganic layer 343 may extend along the upper and outer sides of the blocking pattern layer 600, and may extend further along the outer side of the insulating layer 510 located below the bank 333. The end of the second inorganic layer 343 may be located further outside the end of the first inorganic layer 341.

As described above, the encapsulation layer 200 and the blocking pattern layer 600 in the first non-display area NDA1 may have the same structure as the encapsulation layer 200 and the blocking pattern layer 600 in the second to fourth non-display areas NDA2 to NDA4.

Accordingly, the order of each end of the intermediate layer EL, the common electrode CE, the capping layer 510, the first inorganic layer 341, the organic layer 342, and the second inorganic layer 343 in the first non-display area NDA1 may be the same as the order of each end of the intermediate layer EL, the common electrode CE, the capping layer 510, the first inorganic layer 341, the organic layer 342, and the second inorganic layer 343 in the second to fourth non-display areas NDA2 to NDA4.

Referring to FIGS. 10A and 10B, the inorganic pattern layer 710 and the organic pattern layer 720 included in the blocking pattern layer 600 may be located on the upper portion of the edge portion 333e of the bank 333. The inorganic pattern layer 710 may be disposed on a side of the organic layer 342, and the organic pattern layer 720 may be disposed on a side of the inorganic pattern layer 710.

Referring to FIGS. 10A and 10B, the first inorganic pattern layer 710a and the second inorganic pattern layer 710b included in the inorganic pattern layer 710 may be located on the side of the organic layer 342. The first inorganic pattern layer 710a and the second inorganic pattern layer 710b may be located between the first inorganic layer 341 and the second inorganic layer 342, and may be stacked in a vertical direction. That is, the first inorganic pattern layer 710a may be located on the first inorganic layer 341, and the second inorganic pattern layer 710b may be located on the first inorganic pattern layer 710a.

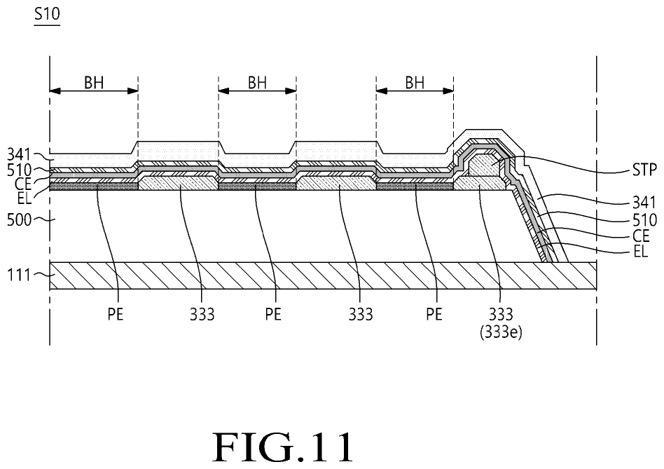

FIGS. 11 to 15 illustrate a method of manufacturing a display device 100 according to embodiments of the present disclosure.

Referring to FIGS. 11, 12, 13, and 15, a manufacturing method of the display device 100 according to embodiments of the present disclosure may include a first step (S10) of forming transistors and a light emitting device and forming a first inorganic layer 341 on the light emitting device, a second step (S20) of forming a blocking pattern layer 600, a third step (S30) of forming the organic layer 342, and a fifth step (S50) of forming the second inorganic layer 343.

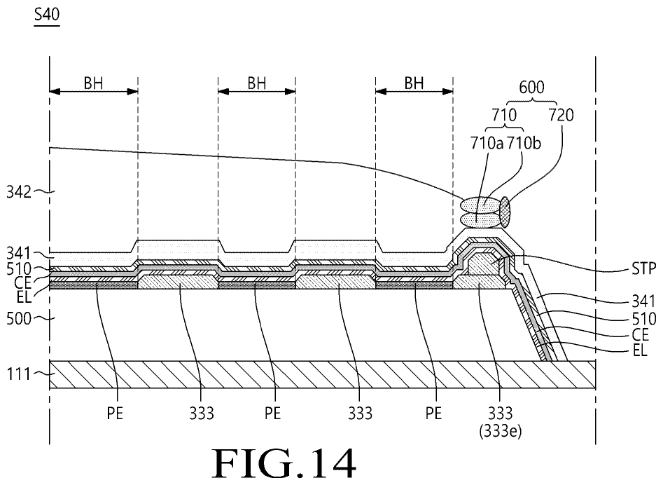

Referring to FIG. 14, a manufacturing method of the display device 100 according to embodiments of the present disclosure may further include a fourth step (S40) of removing the organic sacrificial layer 1200 before the fifth step (S50).

Referring to FIG. 11, in the first step (S10), an insulating layer 500 may be disposed on the substrate 111 including the display area DA and the non-display area NDA, and a bank 333 having a bank hole BH for defining an emission area may be disposed on the insulating layer 500, and a first inorganic layer 341 may be disposed on the bank 333.

In the first step (S10), in order to form light emitting devices, pixel electrodes PE may be disposed, a bank 333 having a bank hole BH overlapping at least a portion of each of the pixel electrodes PE may be disposed, an intermediate layer EL may be disposed on the bank 333 and the pixel electrodes PE, a common electrode CE may be disposed on the intermediate layer EL, a capping layer 510 may be disposed on the common electrode CE, and a first inorganic layer 341 may be disposed on the capping layer 510.

In each bank hole BH, the pixel electrode PE, the intermediate layer EL, and the common electrode CE may overlap with each other to form a light emitting device.

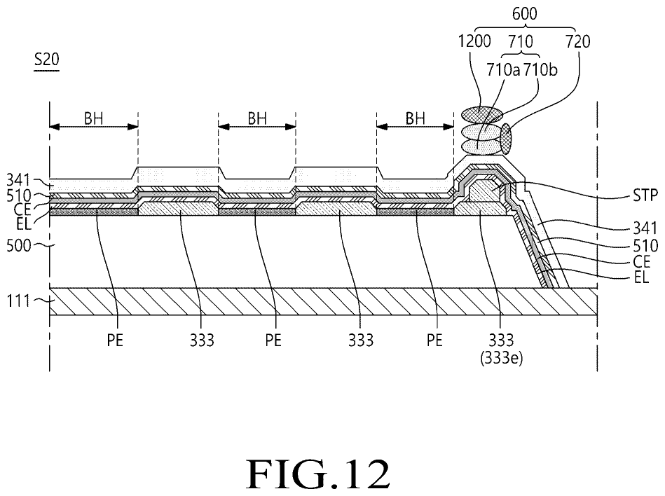

Referring to FIG. 12, in the second step (S20), the blocking pattern layer 600 may be disposed on the first inorganic layer 341, and the blocking pattern layer 600 may be disposed to overlap with at least a portion of the edge portion 333e of the bank 333.

In the second step (S20), the blocking pattern layer 600 may include an inorganic pattern layer 710 on the first inorganic layer 341, an organic sacrificial layer 1200 on the inorganic pattern layer 710, and an organic pattern layer 720 disposed on the outer side of the pattern layer 710.

The organic pattern layer 720 may include a getter for moisture absorption.

In the second step (S20), the inorganic pattern layer 710 may include a first inorganic pattern layer 710a on the first inorganic layer 341 and a second inorganic pattern layer 710b on the first inorganic pattern layer 710a.

As an example, a deposition process using a mask with circular openings and wet etching may be repeatedly performed, so that the first inorganic pattern layer 710a, the second inorganic pattern layer 710b, and the organic sacrificial layer 1200 may be sequentially formed into the desired shape (e.g., circular). In addition, the organic pattern layer 720 may also be formed during forming the organic sacrificial layer 1200.

As another example, an inorganic material and an organic materials may be sequentially injected to a forming frame corresponding to the final shape of the first inorganic pattern layer 710a, the second inorganic pattern layer 710b, the organic pattern layer 720, and the organic sacrificial layer 1200, so that the first inorganic pattern layer 710a, the second inorganic pattern layer 710b, the organic pattern layer 720, and the organic sacrificial layer 1200 may be formed sequentially.

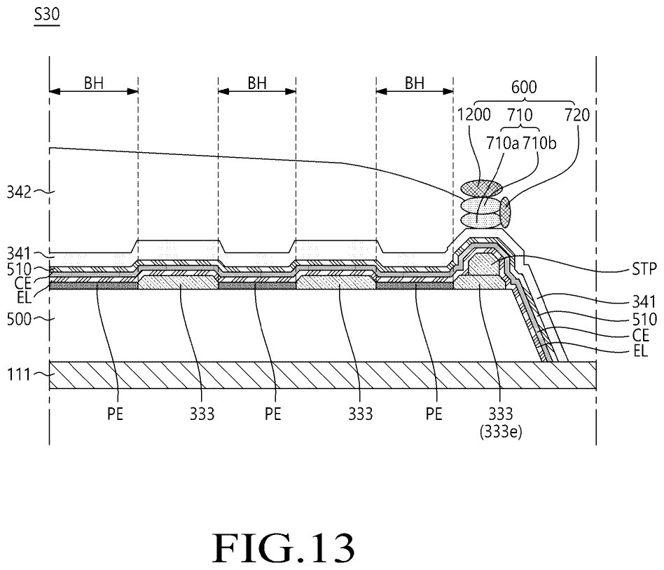

Referring to FIG. 13, in the third step (S30), the organic layer 342 may be disposed on the first inorganic layer 341, and the organic layer 342 may be disposed on the inner surface of the blocking pattern layer 600.

In the third step (S30), the flow of the organic layer 342 may stop at an upper portion of the edge portion 333e of the bank 333.

In the third step (S30), since the side and upper surfaces of the blocking pattern layer 600 have a curved shape, the flow of the organic layer 342 may be slowed. Accordingly, overflow of the organic layer 342 may be prevented or the degree of overflow of the organic layer 342 may be reduced.

For example, in the third step (S30), the organic layer 342 may be formed through a deposition process.

As another example, in the third step (S30), the organic layer 342 may be formed through an inkjet process. If the organic layer 342 is formed through an inkjet process, there may be more noticeable the overflow prevention effect of the organic layer 342 by the blocking pattern layer 600.

Referring to FIG. 14, in the fourth step (S40), as the organic sacrificial layer 1200 is removed, the height of the blocking pattern layer 600 may be lowered. In the fourth step (S40), as the organic sacrificial layer 1200 is removed, the size of a step between the organic layer 342 and the blocking pattern layer 600 may be reduced. The size of the step between the organic layer 342 and the blocking pattern layer 600 may be reduced, thereby preventing the second inorganic layer 343 from being disconnected due to the blocking pattern layer 600, and thus, there may be prevented the defects in reliability of the encapsulation layer 200.

In the fourth step (S40), for example, the organic sacrificial layer 1200 may be removed through an oxygen plasma process.

In the fourth step (S40), even if the organic sacrificial layer 1200 is removed, since the organic pattern layer 720 exists, the moisture absorption function may be maintained by the organic pattern layer 720.

In the fifth step (S50) after the fourth step (S40), the blocking pattern layer 600 may not include the organic sacrificial layer 1200, but may include the first inorganic pattern layer 710a, the second inorganic pattern layer 710b, and an organic pattern layer 720.

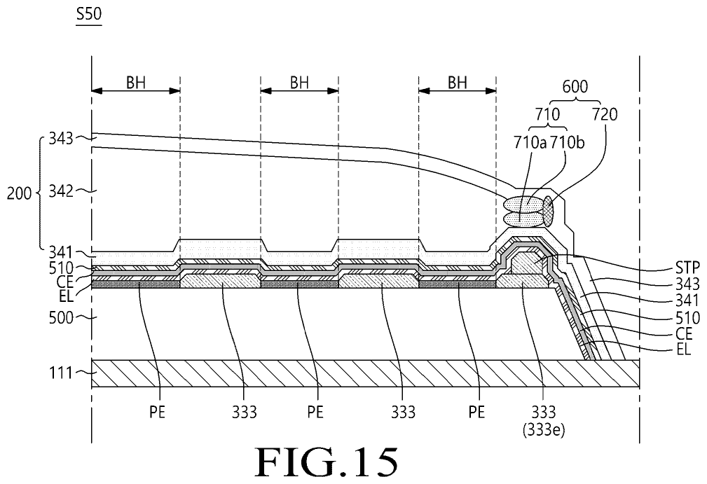

Referring to FIG. 15, in the fifth step (S50), the second inorganic layer 343 may be disposed on the organic layer 342 and the blocking pattern layer 600, and the second inorganic layer 343 may be disposed to extend to the outer side of the pattern layer 600.

Since the blocking pattern layer 600 to prevent overflow of the organic layer 342 is formed on the edge portion 333e of the bank 333, the overflow of the organic layer 342 may be prevented without increasing the bezel size.

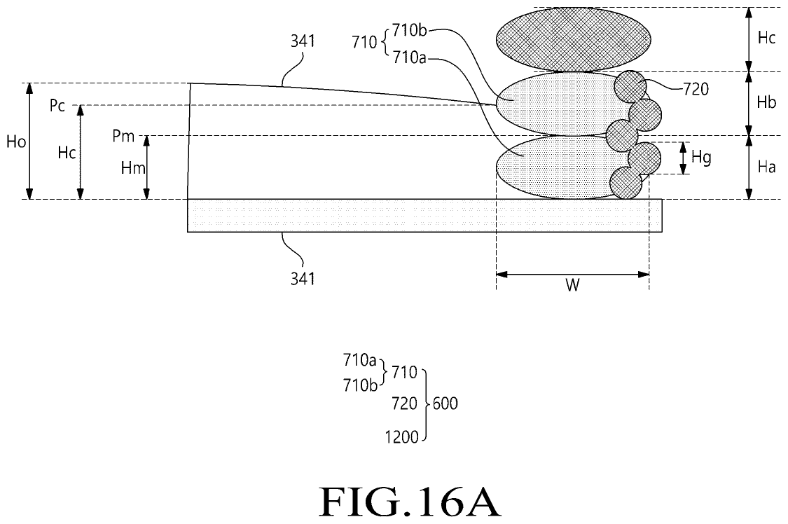

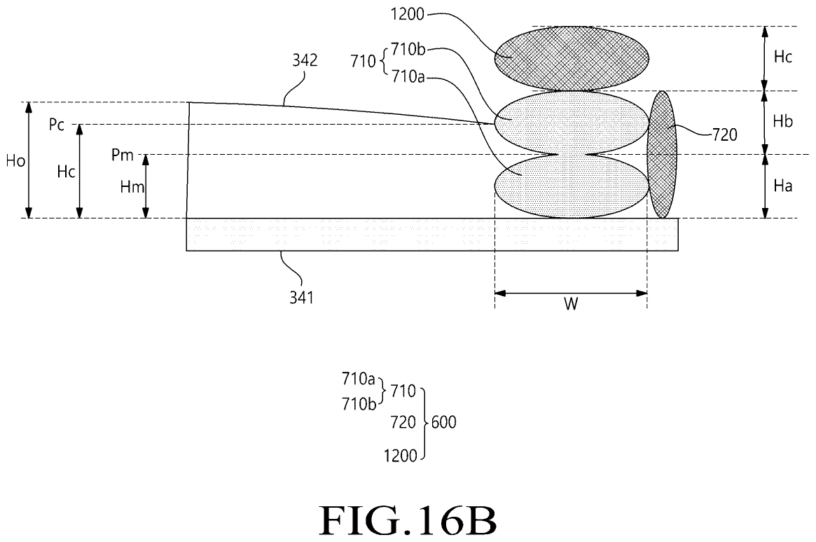

FIGS. 16A and 16B are diagrams for explaining a structure of a vertically stacked blocking pattern layer 600 in a display panel 110 according to embodiments of the present disclosure.

FIG. 16A is a cross-sectional view in the second step (S20) of forming the vertically stacked blocking pattern layer 600 in FIG. 7A, and FIG. 16B is a cross-sectional view in the second step (S20) of forming the vertically stacked blocking pattern layer 600 in FIG. 7B.

Referring to FIG. 16A, as an example, the organic pattern layer 720 may have a size Hg smaller than a size Ha of the first inorganic pattern layer 710a and the size Ha or Hb of the second inorganic pattern layer 710b.

Referring to FIG. 16B, as another example, the organic pattern layer 720 may have a height corresponding to the value Ha+Hb which is the sum of the size Ha of the first inorganic pattern layer 710a and the sizes Ha or Hb of the second inorganic pattern layer 710b.

Referring to FIGS. 16A and 16B, a contact point Pc between the organic layer 342 and the second inorganic pattern layer 710b may be located higher in the first inorganic layer 341 than a contact point Pm between the first inorganic pattern layer 710a and the second inorganic pattern layer 710b. That is, a distance Hc between the contact point Pc between the organic layer 342 and the second inorganic pattern layer 710b and the first inorganic layer 341 may be greater than a distance Hm between the contact point Pm between the first inorganic pattern layer 710a and the second inorganic pattern layer 710b and the first inorganic layer 341.

A thickness Ho of the organic layer 342 may be equal to or greater than the distance Hc between the contact point Pc between the organic layer 342 and the second inorganic pattern layer 710b and the first inorganic layer 341.

Referring to FIGS. 16A and 16B, a width W of the first inorganic pattern layer 710a and the second inorganic pattern layer 710b may be set to be less than or equal to a width of the edge portion 333e of the bank 333.

Hereinafter, it will be described a horizontally stacked blocking pattern layer 600 in more detail.

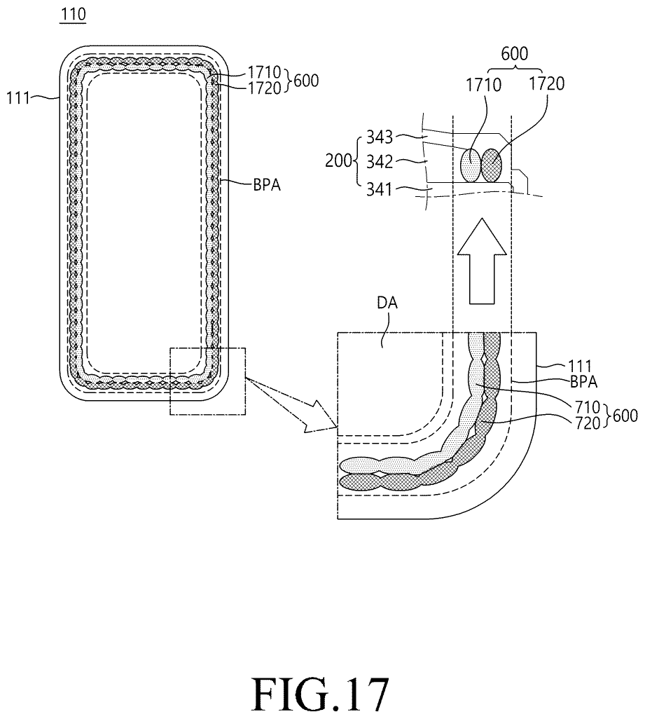

FIG. 17 is a plan view of the display panel 110 according to embodiments of the present disclosure, and illustrates a top view of the display panel 110 including a horizontally stacked blocking pattern layer 600.

Referring to FIG. 17, the display panel 110 according to embodiments of the present disclosure may include a blocking pattern layer 600 disposed on a blocking pattern area BPA defined to prevent overflow of the organic layer 342 included in the encapsulation layer 200.

Referring to FIG. 17, the blocking pattern layer 600 may be disposed in the non-display area NDA, and may be located surrounding the display area DA.

Referring to FIG. 17, the inorganic pattern layer 710 may be formed by connecting patterns having a circular or oval shape. The inner surface of the inorganic pattern layer 710 may be connected to a round curved surface 1750.

Referring to FIG. 17, the inner surface of the inorganic pattern layer 710 is formed as a round curved surface 750, so that the flow of the organic layer 342 may become even slower during the formation of the organic layer 342 included in the encapsulation layer 200. Accordingly, there may be effectively prevented the overflow of the organic layer 342 included in the encapsulation layer 200.

Referring to FIG. 17, the organic pattern layer 720 may block moisture. To this end, the organic pattern layer 720 may include a getter.

Referring to FIG. 17, if the blocking pattern layer 600 is a horizontally stacked type, the blocking pattern layer 600 may include an inorganic pattern layer 710 on the first inorganic layer 341, and an organic pattern layer 720 disposed on the outer side of the inorganic pattern layer 710.

Referring to FIG. 17, the organic pattern layer 720 may include a getter to absorb moisture.

Referring to FIG. 17, the inorganic pattern layer 710 may be disposed surrounding the display area DA from a plan view, and the organic pattern layer 720 may be disposed surrounding the inorganic pattern layer 710 from a plan view.

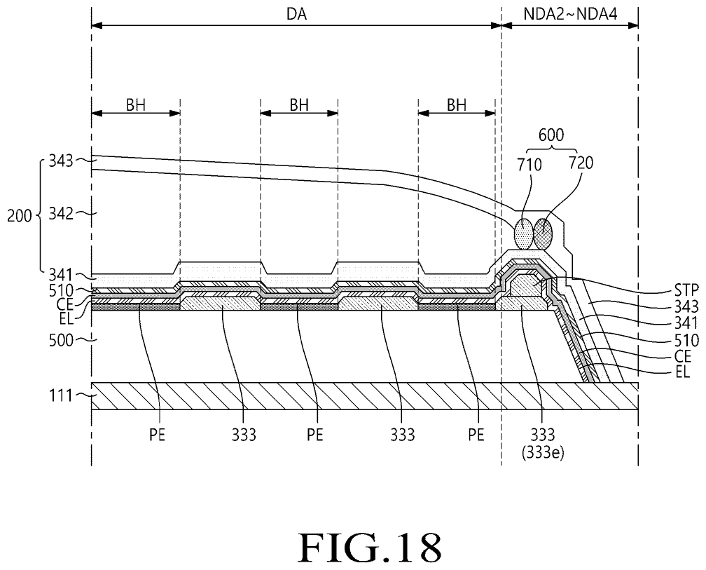

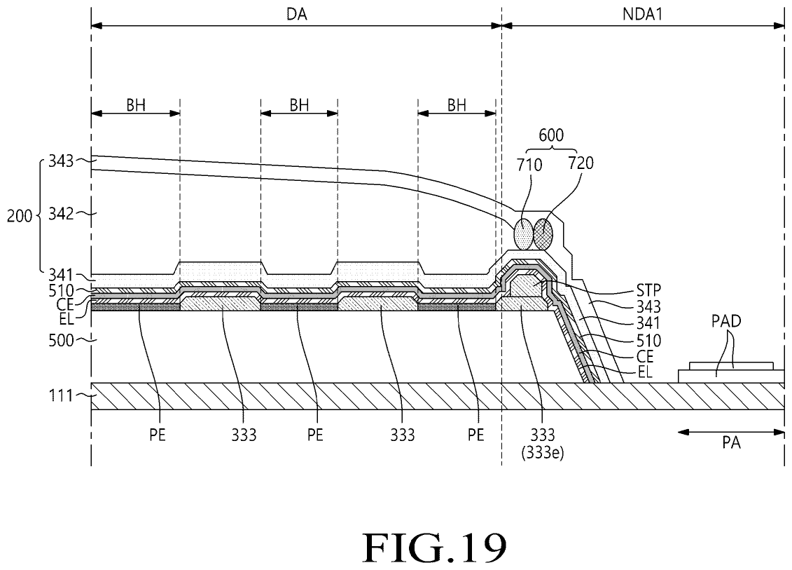

FIGS. 18 and 19 are cross-sectional views of the display panel 110 according to embodiments of the present disclosure, including a horizontally stacked blocking pattern layer 600.

The cross-sectional views of FIGS. 18 and 19 correspond to the cross-sectional views of FIGS. 8 and 9, respectively. That is, the cross-sectional views of FIGS. 18 and 19 are different from the cross-sectional views of FIGS. 8 and 9 in that the blocking pattern layer 600 is a horizontally stacked type, but the remaining configuration is the same as the cross-sectional views of FIGS. 8 and 9. Accordingly, the following description will be made from the perspective of the horizontally stacked blocking pattern layer 600, which is different from the cross-sectional views of FIGS. 8 and 9.

Referring to FIGS. 18 and 19, the display panel 110 according to embodiments of the present disclosure may include a first inorganic layer 341 located on the bank 333, a blocking pattern layer 600 located on the first inorganic layer 341, an organic layer 342 located on the first inorganic layer 341 and disposed on the inner surface of the blocking pattern layer 600, and a second inorganic layer 343 located on the organic layer 342 and extending to an upper portion of the blocking pattern layer 600.

Referring to FIGS. 18 and 19, the blocking pattern layer 600 may be located on the first inorganic layer 341, and may be disposed on the side of the organic layer 342.

Referring to FIGS. 18 and 19, the blocking pattern layer 600 may be located on the first inorganic layer 341, and may be located on an edge portion 333e, which is the outermost portion of the bank 333. That is, the blocking pattern layer 600 may overlap with the edge portion 333e of the bank 333.

Referring to FIGS. 18 and 19, since the blocking pattern layer 600 is located on the edge portion 333e of the bank 333, the blocking pattern layer 600 may be disposed further outside the outermost light emitting device (i.e., outermost emission area) among the light emitting devices (i.e., emission areas).

Referring to FIGS. 18 and 19, the inorganic pattern layer 710 may be disposed on the side (e.g., outer side) of the organic layer 342, and the organic pattern layer 720 may be disposed on the outer side of the inorganic pattern layer 710.

Referring to FIGS. 18 and 19, the second inorganic layer 343 may be located on the organic layer 342, and may extend to the top of the inorganic pattern layer 710 and the top of the organic pattern layer 720. The second inorganic layer 343 may extend further from the top of the organic pattern layer 720 to the outer side of the organic pattern layer 720. The second inorganic layer 343 may extend from the outer side of the organic pattern layer 720 to the outer side of each of the stopper STP, the edge portion 333e of the bank 333, and the insulating layer 500.

Referring to FIG. 18, the second to fourth non-display areas NDA2 to NDA4 do not include the pad area PA. Referring to FIG. 19, the first non-display area NDA1 may further include a pad area PA where a pad PAD is disposed.

Referring to FIGS. 18 and 19, the encapsulation layer 200 and the blocking pattern layer 600 in the first non-display area NDA1 may have the same structure as the encapsulation layer 200 and the blocking pattern layer 600 in the second to fourth non-display areas NDA2 to NDA4.

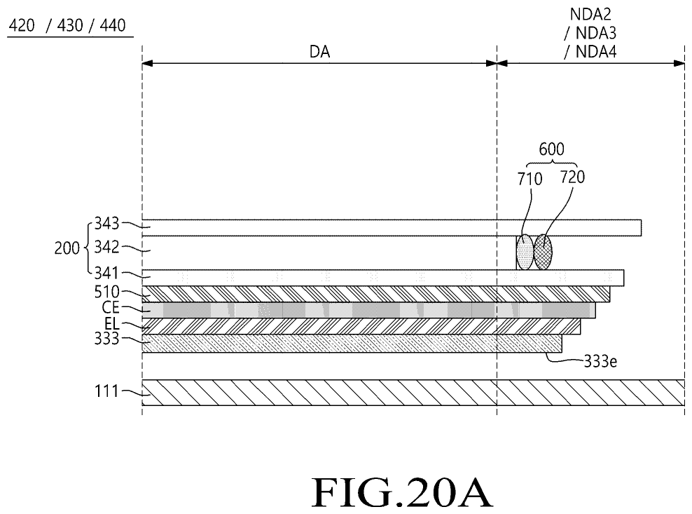

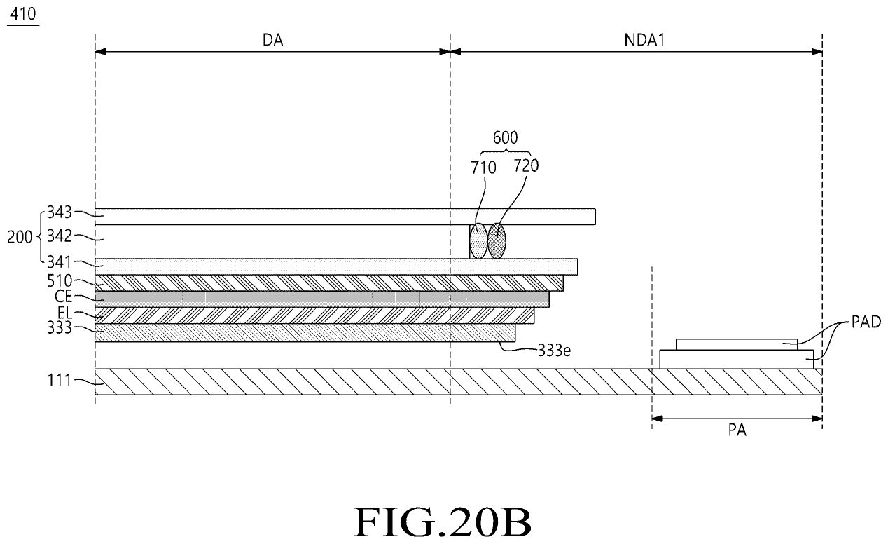

FIGS. 20A and 20B illustrate the end positions of the main layers 333, EL, CE, 800, 341, 342, and 343 of the display panel 110 according to embodiments of the present disclosure.

Referring to FIGS. 20A and 20B, the intermediate layer EL may be located on the bank 333, the common electrode CE may be located on the intermediate layer EL, the capping layer 510 may be located on the common electrode CE, and the encapsulation layer 200 including the first inorganic layer 341, the organic layer 342 and the second inorganic layer 343 may be located on the capping layer 510.

Referring to FIGS. 20A and 20B, the blocking pattern layer 600 may be disposed on the side of the organic layer 342. The blocking pattern layer 600 may be located on the edge portion 333e of the bank 333.

Referring to FIGS. 20A and 20B, the intermediate layer EL, the common electrode CE, the capping layer 510, and the first inorganic layer 341 may extend along the upper and outer side of the edge portion 333e of the bank 333, and may extend further along the outer side of the insulating layer 510 located below the bank 333.

Therefore, the end of the intermediate layer EL may be located further outside the end of the bank 333, the end of the common electrode CE may be located further outside than the end of the intermediate layer EL. In addition, the end of the capping layer 510 may be located further outside the end of the common electrode CE, and the end of the first inorganic layer 341 may be located further outside than the end of the capping layer 510.

Referring to FIGS. 20A and 20B, the second inorganic layer 343 may extend along the upper and outer sides of the blocking pattern layer 600, and may extend further along the outer side of the insulating layer 510 located below the bank 333. The end of the second inorganic layer 343 may be located further outside the end of the first inorganic layer 341.

As described above, the encapsulation layer 200 and the blocking pattern layer 600 in the first non-display area NDA1 may have the same structure as the encapsulation layer 200 and the blocking pattern layer 600 in the second to fourth non-display areas NDA2 to NDA4.

Accordingly, the order of the ends of the intermediate layer EL, the common electrode CE, the capping layer 510, the first inorganic layer 341, the organic layer 342, and the second inorganic layer 343 in the first non-display area NDA1 may be the same as the order of ends of the intermediate layer EL, the common electrode CE, the capping layer 510, the first inorganic layer 341, and organic layer 342 and the second inorganic layer 343 in the second to fourth non-display areas NDA2 to NDA4.

Referring to FIGS. 20A and 20B, the inorganic pattern layer 710 and the organic pattern layer 720 included in the blocking pattern layer 600 may be located on the upper portion of the edge portion 333e of the bank 333.

Referring to FIGS. 20A and 20B, the inorganic pattern layer 710 and the organic pattern layer 720 may be located between the first inorganic layer 341 and the second inorganic layer 342, and the heights of the inorganic pattern layer 710 and the organic pattern layer 720 may correspond to each other.

Referring to FIGS. 20A and 20B, the inorganic pattern layer 710 and the organic pattern layer 720 may be located between the first inorganic layer 341 and the second inorganic layer 342, and may be stacked in the horizontal direction. That is, the inorganic pattern layer 710 may be located on the outer side of the organic layer 342, and the organic pattern layer 720 may be located on the outer side of the inorganic pattern layer 710.

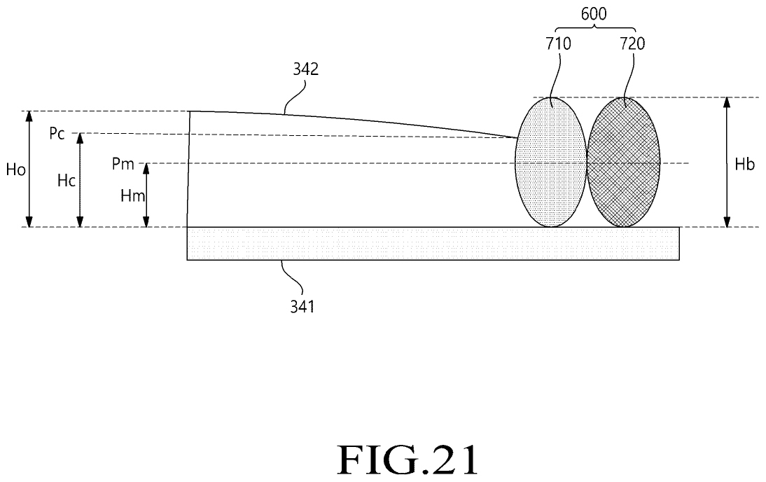

FIG. 21 is a diagram for explaining a structure of the blocking pattern layer 600 in the display panel 110 according to embodiments of the present disclosure.

Referring to FIG. 21, the heights Hb of each of the inorganic pattern layer 710 and the organic pattern layer 720 may correspond to each other.

A contact point Pc between the organic layer 342 and the inorganic pattern layer 710 may be located higher in the first inorganic layer 341 than a midpoint Pm of the inorganic pattern layer 710. In other words, a distance Hc between the contact point Pc between the organic layer 342 and the inorganic pattern layer 710 and the first inorganic layer 341 may be greater than a distance Hm between the midpoint Pm of the inorganic pattern layer 710 and the first inorganic layer 341.

A thickness Ho of the organic layer 342 may be greater than or equal to the distance Hc between the contact point Pc between the organic layer 342 and the inorganic pattern layer 710 and the first inorganic layer 341.

Embodiments of the present disclosure described above are briefly described as follows.

A display device according to embodiments of the present disclosure may include a substrate including a display area and a non-display area, an insulating layer located on the substrate, a bank located on the insulating layer and having a bank hole, a first inorganic layer located on the bank, an organic layer located on the first inorganic layer, a blocking pattern layer located on the first inorganic layer, disposed on a side of the organic layer, and overlapping with at least a portion of an edge portion of the bank, and a second inorganic layer located on the organic layer and extending above the blocking pattern layer.

In the display device according to embodiments of the present disclosure, the blocking pattern layer may be disposed in the non-display area, and may be disposed surrounding the display area.

In the display device according to embodiments of the present disclosure, an inner surface of the blocking pattern layer may have round curved surfaces.

In the display device according to embodiments of the present disclosure, the blocking pattern layer may include an inorganic pattern layer on the first inorganic layer, and an organic pattern layer disposed on an outer side of the inorganic pattern layer.

In the display device according to embodiments of the present disclosure, the inorganic pattern layer may be formed by connecting patterns having a circular or oval shape.

In the display device according to embodiments of the present disclosure, the organic pattern layer may include a getter.

In the display device according to embodiments of the present disclosure, the inorganic pattern layer may include a first inorganic pattern layer on the first inorganic layer, and a second inorganic pattern layer on the first inorganic pattern layer.

In the display device according to embodiments of the present disclosure, the organic pattern layer may have a size smaller than a size of the first inorganic pattern layer and a size of the second inorganic pattern layer, or the organic pattern layer may have a height corresponding to the sum of the size of the first inorganic pattern layer and the size of the second inorganic pattern layer.

In the display device according to embodiments of the present disclosure, a contact point between the organic layer and the second inorganic pattern layer may be located higher in the first inorganic layer than a contact point between the first inorganic pattern layer and the second inorganic pattern layer.

In the display device according to embodiments of the present disclosure, the inorganic pattern layer may be disposed surrounding the display area, and the organic pattern layer may be disposed surrounding the inorganic pattern layer.

In the display device according to embodiments of the present disclosure, a height of the inorganic pattern layer may correspond to a height of the organic pattern layer.

In the display device according to embodiments of the present disclosure, a contact point between the organic layer and the inorganic pattern layer may be located higher in the first inorganic layer than a midpoint of the inorganic pattern layer.

The display device according to embodiments of the present disclosure may further include a stopper located between the edge portion of the bank and the first inorganic layer.

The display device according to embodiments of the present disclosure may further include a pixel electrode on the insulating layer, an intermediate layer on the pixel electrode, and a common electrode on the intermediate layer.

In the display device according to embodiments of the present disclosure, the first inorganic layer may be located on the common electrode.

In the display device according to embodiments of the present disclosure, the bank hole may overlap with at least a portion of the pixel electrode.

In the display device according to embodiments of the present disclosure, the intermediate layer and the common electrode may extend along a side of the insulating layer past an upper portion of the edge portion of the bank.

In the display device according to embodiments of the present disclosure, the first inorganic layer may be disposed in the display area, may extend along a side of the insulating layer past an upper portion of the edge portion of the bank, and may be also disposed in at least a portion of the non-display area.

In the display device according to embodiments of the present disclosure, the second inorganic layer may be disposed in the display area, may extend to an outer side of the blocking pattern layer past an upper portion of the blocking pattern layer, and may be also disposed in at least a portion of the non-display area.

A method of manufacturing a display device according to embodiments of the present disclosure may include a step of disposing an insulating layer on a substrate including a display area and a non-display area, disposing a bank having a bank hole for defining an emission area on the insulating layer, and disposing a first inorganic layer on the bank, a step of disposing a blocking pattern layer on the first inorganic layer, and disposing the blocking pattern layer to overlap with at least a portion of an edge portion of the bank, a step of disposing an organic layer on the first inorganic layer, and disposing the organic layer on an inner surface of the blocking pattern layer, and a step of disposing a second inorganic layer on the organic layer and the blocking pattern layer, and disposing the second inorganic layer so that the second inorganic layer extends to an outer side of the blocking pattern layer.

In the method of manufacturing a display device according to embodiments of the present disclosure, in the step of disposing the blocking pattern layer, the blocking pattern layer may include an inorganic pattern layer on the first inorganic layer, an organic sacrificial layer on the inorganic pattern layer, and an organic pattern layer disposed on an outer side of the inorganic pattern layer.

In the method of manufacturing a display device according to embodiments of the present disclosure, the organic pattern layer may include a getter.

In the method of manufacturing a display device according to embodiments of the present disclosure, in the step of disposing the blocking pattern layer, the inorganic pattern layer may include a first inorganic pattern layer on the first inorganic layer, and a second inorganic pattern layer on the first inorganic pattern layer.

The method of manufacturing a display device according to embodiments of the present disclosure may further include a step of removing the organic sacrificial layer before disposing the second inorganic layer.

In the method of manufacturing a display device according to embodiments of the present disclosure, in the step of disposing the second inorganic layer, the blocking pattern layer may include the first inorganic pattern layer, the second inorganic pattern layer, and the organic pattern layer.

According to the embodiments of the present disclosure described above, it is possible to provide a display device capable of effectively preventing the spread and overflow of an organic layer.

According to embodiments of the present disclosure, it is possible to provide a display device having a structure capable of effectively preventing the spread and overflow of an organic layer while implementing an extremely narrow bezel.

According to embodiments of the present disclosure, it is possible to provide a display device having a structure capable of effectively preventing the spread and overflow of an organic layer, implementing an extremely narrow bezel, and also performing a moisture absorption function.

According to embodiments of the present disclosure, it is possible to reduce the weight of a display device by having an extremely narrow bezel structure.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display device, comprising:
a substrate including a display area and a non-display area;
an insulating layer on the substrate;
a bank on the insulating layer;
a bank hole included in the bank;
a first inorganic layer on the bank;
an organic layer on the first inorganic layer;
a blocking pattern layer located on the first inorganic layer, disposed on a side of the organic layer, and overlapping with at least a portion of an edge portion of the bank; and
a second inorganic layer on the organic layer and extending above the blocking pattern layer.

2. The display device of claim 1, wherein the blocking pattern layer is disposed in the non-display area, and is disposed to surround the display area.

3. The display device of claim 1, wherein an inner surface of the blocking pattern layer has round curved surfaces.

4. The display device of claim 1, wherein the blocking pattern layer comprises:
an inorganic pattern layer on the first inorganic layer; and
an organic pattern layer disposed on an outer side of the inorganic pattern layer.

5. The display device of claim 4, wherein the inorganic pattern layer is formed by connecting patterns having a circular or oval shape.

6. The display device of claim 4, wherein the organic pattern layer includes a getter.

7. The display device of claim 4, wherein the inorganic pattern layer comprises:
a first inorganic pattern layer on the first inorganic layer; and
a second inorganic pattern layer on the first inorganic pattern layer.

8. The display device of claim 7, wherein the organic pattern layer has a size smaller than a size of the first inorganic pattern layer and a size of the second inorganic pattern layer, or the organic pattern layer has a height corresponding to a sum of the size of the first inorganic pattern layer and the size of the second inorganic pattern layer.

9. The display device of claim 7, wherein a contact point between the organic layer and the second inorganic pattern layer is located higher in the first inorganic layer than a contact point between the first inorganic pattern layer and the second inorganic pattern layer.

10. The display device of claim 4, wherein the inorganic pattern layer is disposed surrounding the display area from a plan view, and the organic pattern layer is disposed surrounding the inorganic pattern layer from a plan view.

11. The display device of claim 4, wherein a height of the inorganic pattern layer corresponds to a height of the organic pattern layer, and
wherein a contact point between the organic layer and the inorganic pattern layer is located higher in the first inorganic layer than a midpoint of the inorganic pattern layer.

12. The display device of claim 1, further comprising a stopper located between the edge portion of the bank and the first inorganic layer.

13. The display device of claim 1, further comprising:
a pixel electrode on the insulating layer;
an intermediate layer on the pixel electrode; and
a common electrode on the intermediate layer,
wherein the first inorganic layer is on the common electrode,
wherein the bank hole overlaps with at least a portion of the pixel electrode, and
wherein the intermediate layer and the common electrode extend along a side of the insulating layer past an upper portion of the edge portion of the bank.

14. The display device of claim 1, wherein the first inorganic layer is disposed in the display area, extends along a side of the insulating layer past an upper portion of the edge portion of the bank, and is also disposed in at least a portion of the non-display area.

15. The display device of claim 1, wherein the second inorganic layer is disposed in the display area, extends to an outer side of the blocking pattern layer past an upper portion of the blocking pattern layer, and is also disposed in at least a portion of the non-display area.

16. A method of manufacturing a display device, comprising:
disposing an insulating layer on a substrate including a display area and a non-display area;
disposing a bank having a bank hole for defining an emission area on the insulating layer;
disposing a first inorganic layer on the bank;
disposing a blocking pattern layer on the first inorganic layer, and disposing the blocking pattern layer to overlap with at least a portion of an edge portion of the bank;
disposing an organic layer on the first inorganic layer, and disposing the organic layer on an inner surface of the blocking pattern layer; and
disposing a second inorganic layer on the organic layer and the blocking pattern layer,
wherein the second inorganic layer is disposed so that the second inorganic layer extends to an outer side of the blocking pattern layer.

17. The method of claim 16, wherein, in disposing the blocking pattern layer, the blocking pattern layer comprises:
an inorganic pattern layer on the first inorganic layer;
an organic sacrificial layer on the inorganic pattern layer; and
an organic pattern layer disposed on an outer side of the inorganic pattern layer.

18. The method of claim 17, wherein the organic pattern layer includes a getter.

19. The method of claim 17, wherein, in disposing the blocking pattern layer, the inorganic pattern layer includes a first inorganic pattern layer on the first inorganic layer, and a second inorganic pattern layer on the first inorganic pattern layer.

20. The method of claim 18, further comprising:
removing the organic sacrificial layer before disposing the second inorganic layer,
wherein, in disposing the second inorganic layer, the blocking pattern layer includes the first inorganic pattern layer, the second inorganic pattern layer, and the organic pattern layer.
